(19) United States
(12) Patent Application Publication
(10) Pub. No.: US 2025/0142945 A1
(43) Pub. Date: May 1, 2025

(54) SEMICONDUCTOR DEVICE AND INTEGRATED CIRCUIT INCLUDING THE SAME

(71) Applicant: Samsung Electronics Co., Ltd., Suwon-si (KR)

(72) Inventors: Sora YOU, Suwon-si (KR); Dongyun LEE, Suwon-si (KR); Seungmin CHA, Suwon-si (KR); Jeewoong KIM, Suwon-si (KR)

(73) Assignee: Samsung Electronics Co., Ltd., Suwon-si (KR)

(21) Appl. No.: 18/634,355

(22) Filed: Apr. 12, 2024

(30) Foreign Application Priority Data
Oct. 27, 2023 (KR) 10-2023-0145953

(51) Int. Cl. H01L 27/06; H01L 23/528; H01L 29/06; H01L 29/423; H01L 29/66; H01L 29/775; H01L 29/861

(52) U.S. Cl. CPC H10D 84/811; H01L 23/5286; H10D 8/043; H10D 8/045; H10D 8/411; H10D 30/014; H10D 30/43; H10D 30/6735; H10D 62/121

(57) ABSTRACT

A semiconductor device may include a diode pattern including a first conductive region and a second conductive region having opposite conductivity types to each other on a base insulating layer, an insulating layer covering the diode pattern on the base insulating layer, a wiring portion on the insulating layer; and a through connector extending through the insulating layer at a periphery of the diode pattern to electrically connect the diode pattern and the wiring portion.

### CROSS-REFERENCE TO RELATED APPLICATION

This application claims priority to and the benefit of Korean Patent Application No. 10-2023-0145953, filed in the Korean Intellectual Property Office on Oct. 27, 2023, the entire contents of which are incorporated herein by reference.

### BACKGROUND

### Field

The present disclosure relates to semiconductor devices and integrated circuits including the same.

### Description of the Related Art

Semiconductor devices may be miniaturized and perform various functions, so they are used in various electronic devices such as storage devices that store data and processors that compute and process data. With the development of the electronics industry, various researches are continuing to improve various properties such as integration, reliability, speed, and functionality of semiconductor devices.

Conventionally, in integrated circuits that include various semiconductor devices, there is a limit to improving properties of various semiconductor devices due to limitations in a manufacturing process.

### SUMMARY

Some example embodiments provide semiconductor devices and integrated circuits including the same that are capable of improving performance and productivity.

According to an example embodiment of the present disclosure, a semiconductor device may include a diode pattern on a base insulating layer, the diode pattern including a first conductive region and a second conductive region having opposite conductivity types to each other, an insulating layer covering the diode pattern on the base insulating layer, a wiring portion on the insulating layer, and a through connector extending through the insulating layer at a periphery of the diode pattern to electrically connect the diode pattern and the wiring portion.

According to an example embodiment of the present disclosure, a semiconductor device may include a diode pattern on a base insulating layer, the diode pattern including a first conductive region and a second conductive region having opposite conductivity types to each other, an insulating layer covering the diode pattern on the base insulating layer, a wiring portion on the insulating layer, and a connector electrically connecting a side surface or a back surface of the diode pattern and the wiring portion.

According to an example embodiment of the present disclosure, an integrated circuit may include a base insulating layer having a first region and a second region, a first semiconductor device in the first region, and a second semiconductor device in the second region, the second semiconductor device including a back power distribution network (BSPDN) structure, the BSPDN structure including a back wiring portion, the back wiring porting including a back contact via extending through the base insulating layer. The first semiconductor device includes a diode pattern on the base insulating layer, the diode pattern including a first conductive region and a second conductive region having opposite conductivity types to each other, an insulating layer covering the diode pattern on the base insulating layer, a wiring portion on the insulating layer, and a through connector extending through the insulating layer at a periphery of the diode pattern and electrically connecting the diode pattern to the wiring portion.

According to an example embodiment, performance of the semiconductor device may be improved by simplifying the structure of the semiconductor device including a diode with a bulk-less structure and ameliorating the resistance. Furthermore, semiconductor devices may be manufactured through a relatively easy manufacturing process, thereby improving productivity of the semiconductor devices.

Furthermore, a structure of an integrated circuit including the above-described semiconductor device together with a semiconductor device having a back power distribution network structure may be simplified, and the integrated circuit may be formed through a relatively easy manufacturing process.

### BRIEF DESCRIPTION OF THE DRAWINGS

FIG. 1 is a plan view illustrating a first semiconductor device according to an example embodiment.

FIG. 2 is a cross-sectional view taken along a line I-I′ of FIG. 1.

FIG. 3 is a cross-sectional view illustrating the first semiconductor device taken along a line X-X′ in FIG. 1 together with a second semiconductor device.

FIG. 4 is a cross-sectional view illustrating the first semiconductor device taken along a line Y-Y′ in FIG. 1 together with a second semiconductor device.

FIG. 5 to FIG. 17 are cross-sectional views illustrating a manufacturing method for an integrated circuit including a first semiconductor device according to an example embodiment.

FIG. 18 is a plan view illustrating a first semiconductor device according to an example embodiment.

FIG. 19 is a cross-sectional view taken along a line A-A of FIG. 18.

FIG. 20 is a cross-sectional view illustrating the first semiconductor device taken along a line B-B′ in FIG. 18 together with a second semiconductor device.

FIG. 21 to FIG. 24 are cross-sectional views showing a manufacturing method for an integrated circuit including a first semiconductor device according to an example embodiment.

### DETAILED DESCRIPTION

Some example embodiments of the present disclosure will be described more fully hereinafter with reference to the accompanying drawings for those skilled in the art to which the present disclosure pertains to easily practice the present disclosure. The present disclosure may be implemented in various different forms and is not limited to the example embodiments provided herein.

A portion unrelated to the description is omitted in order to clearly describe the present disclosure, and the same or similar components are denoted by the same reference numeral throughout the present specification.

Further, since sizes and thicknesses of portions, regions, members, units, layers, films, etc., illustrated in the accompanying drawings may be arbitrarily illustrated for better understanding and convenience of explanation, the present disclosure is not limited to the illustrated sizes and thicknesses. In the drawings, thicknesses of portions, regions, members, units, layers, films, etc., may be enlarged or exaggerated for convenience of explanation and/or simple illustration.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a vertical cross-sectional viewed from a side.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B.

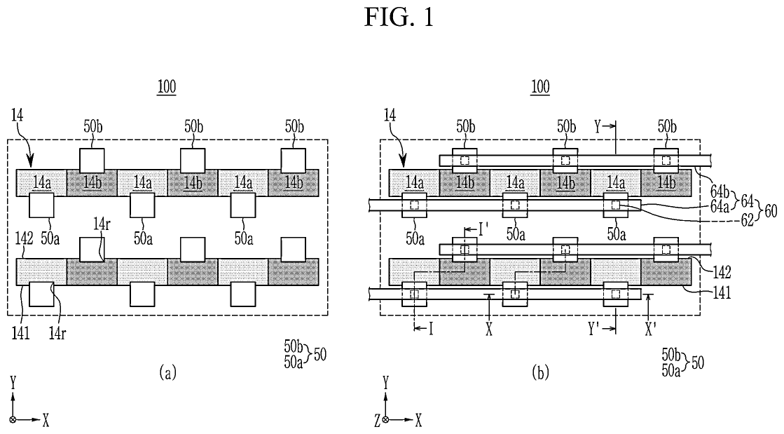

Hereinafter, a semiconductor device and an integrated circuit including the same according to an example embodiment will be described with reference to FIG. 1 to FIG. 4.

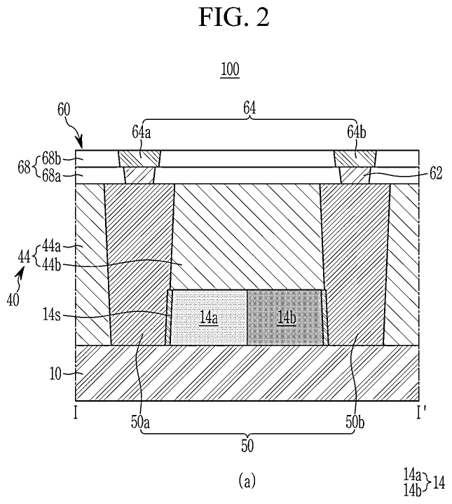

FIG. 1 is a plan view illustrating a first semiconductor device 100 according to an example embodiment, and FIG. 2 is a cross-sectional view taken along a line I-I′ of FIG. 1. For simple illustration and a clear understanding, FIG. 1A illustrates a diode pattern 14 and a through connector 50, and FIG. 1B illustrates the diode pattern 14, the through connector 50, and a wiring portion 60.

Referring to FIG. 1 and FIG. 2, a first semiconductor device 100 according to the example embodiment includes a diode pattern 14 on a base insulating layer 10, an insulating layer 40 (e.g., a first insulating layer 44), a through connector 50, and a wiring portion 60. As an example, the first semiconductor device 100 may be a pn diode having a bulk-less structure. This will be described in more detail.

In an example embodiment, the base insulating layer 10 may be in a lower portion of the first semiconductor device 100 to support the diode pattern 14, the insulating layer 40, the through connector 50, and the wiring portion 60. In an example embodiment, the base insulating layer 10 may be in an entire lower portion of the first semiconductor device 100. For example, the base insulating layer 10 may have a plane (XY plane in the drawing) extending in a first direction (X-axis direction in the drawing) and a second direction (Y-axis direction in the drawing) that is transverse to or crosses (for example, perpendicular to) each other, and may have a desired (or alternatively, predetermined) thickness in a third direction (Z-axis direction in the drawing).

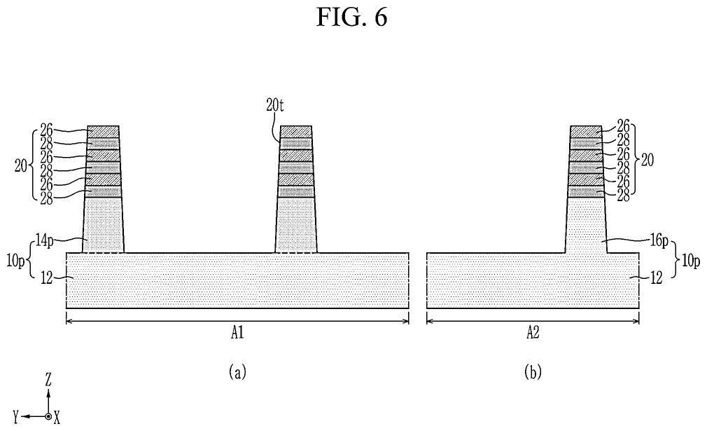

The diode pattern 14 on the base insulating layer 10 may have a separated structure in the second direction (Y-axis direction in the drawing). For example, in a case where a plurality of diode patterns 14 are provided in the second direction, the diode patterns 14 may be on the base insulating layer 10 but may have separate patterns that are separated from each other. That is, after removing a bulk portion 12 (refer to FIG. 6) of a semiconductor substrate 10p (refer to FIG. 6) having the diode patterns 14, the base insulating layer 10 is formed in an area from which the bulk portion 12 has been removed so that the first semiconductor device 100 has a bulk-less structure.

The base insulating layer 10 may include any of various insulating materials. For example, the base insulating layer 10 may include a silicon oxide (SiOₓ), a silicon nitride (SiNₓ), a silicon nitride (SiONₓ), or a combination thereof, but example embodiments are not limited thereto.

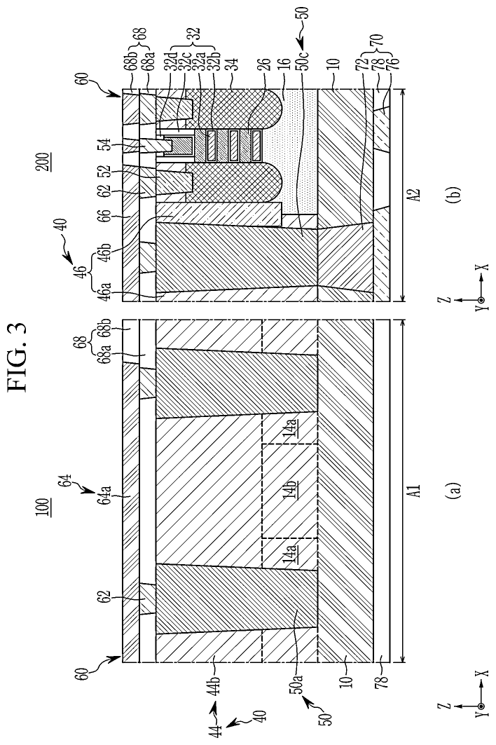

A back insulating layer 78 (refer to FIG. 3) may be further on one surface (e.g., a lower surface) of the base insulating layer 10. When the second semiconductor device 200 is described later with reference to FIG. 3, the back insulating layer 78 will be described. However, example embodiments are not limited thereto and the back insulating layer 78 may not be provided.

The diode pattern 14 including a first conductive region 14a and a second conductive region 14b having opposite conductive types may be on a second surface (e.g., front or top surface) of the base insulating layer 10.

The first conductive region 14a and the second conductive region 14b may each include a semiconductor substrate including a semiconductor material. For example, the first conductive region 14a or the second conductive region 14b may include at least one of a group IV semiconductor, a group III-V compound semiconductor, or a group II-VI compound semiconductor. For example, the first conductive region 14a or the second conductive region 14b may include at least one of Si, Ge, SiGe, SiC, GaAs, InAs, or InP.

In this instant, the first conductive region 14a or the second conductive region 14b may include a crystalline semiconductor substrate (for example, a single crystalline semiconductor substrate or a polycrystalline semiconductor substrate). As another example, the first conductive region 14a or the second conductive region 14b may include an epitaxial semiconductor layer. As such, when the first conductive region 14a and the second conductive region 14b constituting the diode pattern 14 include a crystalline semiconductor material, electrical properties of the first semiconductor device 100 may be improved.

The first conductive region 14a may include a semiconductor material doped with a first conductivity type (e.g., one of p-type or n-type) dopant to have a first conductivity type (e.g., one of p-type or n-type), and the second conductive region 14b may include a semiconductor material doped with a second conductivity type (e.g., the other one of n-type or p-type) dopant to have a second conductivity type (e.g., the other one of n-type or p-type). The first conductive region 14a and the second conductive region 14b adjacent to each other may form a unit diode pattern forming a pn diode.

In an example embodiment, the diode pattern 14 may have a shape longitudinally extending in the first direction (X-axis direction in the drawing), and a plurality of diode patterns 14 may be at regular intervals and spaced apart from each other in the second direction (Y-axis direction in the drawing) that is transverse to the first direction. For example, the plurality of diode patterns 14, each having a constant width in the first direction and a desired (or alternatively, predetermined) thickness in a third direction (Z-axis direction in the drawing), may be spaced apart from each other in the second direction on the base insulation layer 10.

In each of the diode patterns 14, the first conductive region 14a and the second conductive region 14b may be adjacent to each other in the first direction. As an example, each diode pattern 14 may include a plurality of first conductive regions 14a and a plurality of second conductive regions 14b alternately in the first direction. That is, each diode pattern 14 may include a plurality of unit diode patterns.

In the drawings and the above description, each diode pattern 14 includes a plurality of unit diode patterns and the plurality of diode patterns 14 are provided. In some example embodiments, the diode pattern 14 may include one unit diode pattern or one diode pattern 14.

In the drawing, it is illustrated that the plurality of first conductive regions 14a included in each diode pattern 14 have a same area and the plurality of second conductive regions 14b included in each diode pattern 14 have a same area. Furthermore, in the plurality of diode patterns 14 in the second direction, the first conductive region 14a and the second conductive region 14b have a same area and are at a same position. However, example embodiments are not limited thereto. In some example embodiments, the first conductive regions 14a included in each diode pattern 14 may have different areas, and/or the second conductive regions 14b included in each diode pattern 14 may have different areas. In some example embodiments, in the plurality of diode patterns 14 in the second direction, the first conductive region 14a and/or the second conductive region 14b may have different areas or be at different positions. Numerous other variations are possible.

In the drawing, it is illustrated that a length of the first or second conductive region 14a or 14b in the first direction (X-axis direction in the drawing) is greater than a width of the first or second conductive region 14a or 14b in the second direction (Y-axis direction in the drawing). Accordingly, the through connector 50 may have a relatively large pitch. However, example embodiments are not limited thereto, and the length of the first or second conductive region 14a or 14b may be equal to or smaller than the width of the first or second conductive region 14a or 14b.

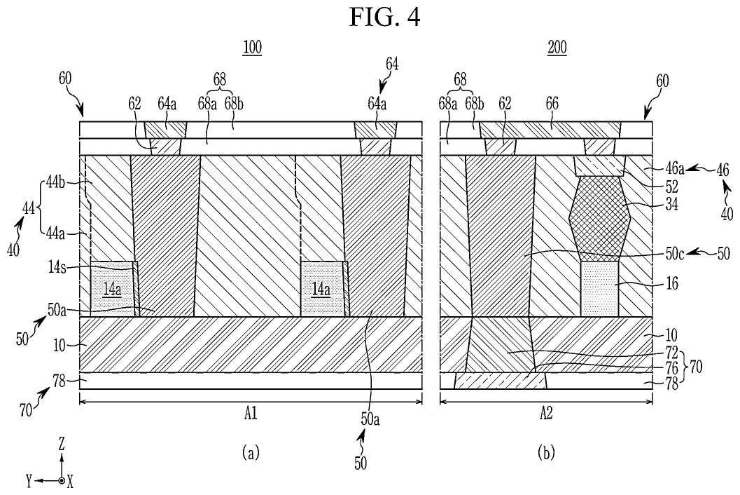

The insulating layer 40 (more particularly, a first insulating layer 44) covering the diode pattern 14 may be on the base insulating layer 10. Referring to FIG. 4 along with FIGS. 1 and 2, in an example embodiment, the first insulating layer 44 may include a first insulating portion 44a and a second insulating portion 44b. The first insulating portion 44a may be on the base insulating layer 10, and the second insulating portion 44b may be on the diode pattern 14. The second insulating portion 44b may also be referred to as an upper insulating portion.

The first insulating portion 44a and the second insulating portion 44b may be formed by different processes. For example, the second insulating portion 44b may be formed by removing a layer (e.g., a stacked structure 20 (refer to FIG. 6, the same hereinafter)) on the diode pattern 14 and forming an insulating material in a corresponding portion. The stacked structure 20 may be used to form a second semiconductor device 200 (refer to FIG. 3), which will be described later. In the first semiconductor device 100 according to the example embodiment, an undesired current path may be formed by the stacked structure 20, and thus, the stacked structure 20 may be removed and the second insulating portion 44b may be formed. A boundary between the first insulating portion 44a and the second insulating portion 44b may be seen or might not be clearly seen.

The first insulating portion 44a and the second insulating portion 44b may include one layer or a plurality of layers. A plurality of layers included in the first insulating portion 44a or the second insulating portion 44b may include a same material or different materials. A boundary between the plurality of layers included in the first insulating portion 44a or the second insulating portion 44b may be seen or might not be clearly seen. The first insulating portion 44a and the second insulating portion 44b may have a same material or different materials. For example, the first insulating portion 44a or the second insulating portion 44b may include at least one of silicon oxide, silicon nitride, silicon oxynitride, or a low dielectric constant material. However, example embodiments are not limited to the above-described structure or material of the first insulation layer 44, the first insulation portion 44a, or the second insulation portion 44b.

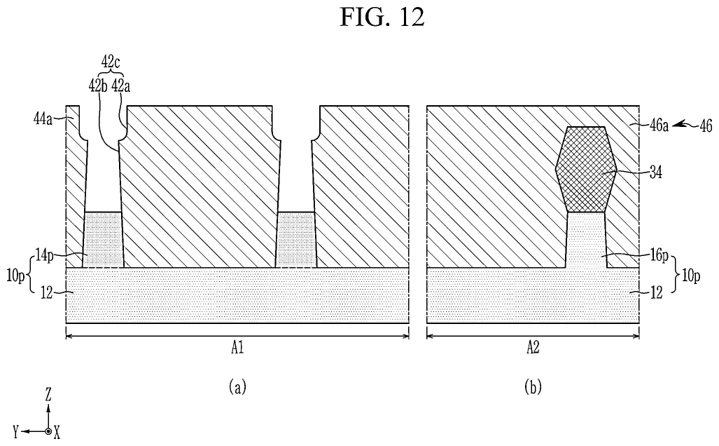

In an example embodiment, the second insulating portion 44b may have portions having different widths and a side surface of the second insulating portion 44b may have a step. For example, a width in the second direction (Y-axis direction of the drawing) may be greater in an upper portion than in a lower portion, and the step where a width in the second direction changes may be provided between the lower portion and the upper portion at the side surface of the second insulating portion 44b. This may be due to a process of forming an opening 42c (refer to FIG. 12) for forming the second insulating portion 44b. This will be described in more detail later in a manufacturing method for the first semiconductor device 100. However, example embodiments are not limited thereto. The side surface of the second insulating portion 44b may be an inclined surface or a vertical surface continuously extended, and the step at the side surface might not be provided.

The wiring portion 60 may be on the first insulating layer 44. Because the wiring portion 60 is at an upper portion of the first semiconductor device 100, the wiring portion 60 may also be referred to as an upper wiring portion or a front wiring portion.

The wiring portion 60 may include a first wiring layer 64, a contact via 62 connecting the through connector 50 and the first wiring layer 64, and an upper insulating layer 68 at a periphery of at least the contact via 62 and the first wiring layer 64 in a portion where the contact via 62 and the first wiring layer 64 are not positioned.

For simple illustration and a clear understanding, it is illustrated in the drawing that the first wiring layer 64 includes a first layer connected to the through connector 50 through the contact via 62. In the drawing, it is illustrated that the upper insulating layer 68 is on the insulating layer 40, and the upper insulating layer 68 includes a first upper insulating layer 68a on a same layer as the contact via 62, and a second upper insulating layer 68b on the first upper insulating layer 68a and on a same layer as the first wiring layer 64. However, the example embodiments are not limited thereto. The first wiring layer 64 may further include one or more additional wiring layers connected to the first layer through a contact via 62 with an insulating layer provided therebetween. Alternatively, a stacked structure and a shape of the upper insulating layer 68 may be modified in various ways.

For example, the first upper insulating layer 68a or the second upper insulating layer 68b may include at least one of silicon oxide, silicon nitride, silicon oxynitride, or a low dielectric constant material. However, example embodiments are not limited to the above, and the first upper insulating layer 68a or the second upper insulating layer 68b may include any of various materials or have any of various structures. A boundary between the first upper insulating layer 68a and the second upper insulating layer 68b may be seen or might not be clearly seen.

The through connector 50 may be at a periphery of the diode pattern 14 to extend through the insulating layer 40 (more particularly, the first insulating layer 44) and electrically connect the diode pattern 14 and the first wiring layer 64. For example, the through connector 50 may contact the diode pattern 14 and the contact via 62. In this instance, the through connector 50 may include a first through connector 50a connected to the first conductive region 14a and a second through connector 50b connected to the second conductive region 14b.

In an example embodiment, the first conductive region 14a and the second conductive region 14b may be adjacent to each other in the first direction (X-axis direction in the drawing). Furthermore, the first through connector 50a may be at a portion where the first conductive region 14a is positioned when viewed in the first direction, and may be at a first side (a lower side in FIG. 1) of the diode pattern 14 in the second direction (Y-axis direction in the drawing). The second through connector 50b may be at a portion where the second conductive region 14b is positioned when viewed in the first direction, and may be at a second side (an upper side in FIG. 1) of the diode pattern 14, which is opposite to the first side of the diode pattern 14 in the second direction (Y-axis direction in the drawing). That is, when viewed in the second direction, the first through connector 50a and the second through connector 50b may be at opposite sides of each other while positioning the diode pattern 14 at a center.

For example, the first through connector 50a may correspond to a central portion of the first conductive region 14a in the first direction, and the second through connector 50b may correspond to a central portion of the second conductive region 14b in the first direction. Accordingly, the first through connector 50a and the first conductive region 14a may be stably connected, and the second through connector 50b and the second conductive region 14b may be stably connected.

In this instance, a plurality of first through connectors 50a electrically connected to a plurality of first conductive regions 14a may be provided at the first side of the diode pattern 14, and a plurality of second through connectors 50b electrically connected to the second conductive regions 14b may be provided at the second side of the diode pattern 14.

In the first direction, the first through connector 50a and the second through connector 50b at opposite sides may be alternately positioned from a first end (a left end in FIG. 1) to a second end (a right end in FIG. 1) of the diode pattern 14. For example, the first through connector 50a and the second through connector 50b may be disposed in a zigzag shape.

In an example embodiment, a voltage or power to operate the first semiconductor device 100 may be applied through the first wiring layer 64. The first wiring layer 64 may include a first wiring portion 64a extending in the first direction at the first side of the diode pattern 14 to be electrically connected to a plurality of first through connectors 50a, and a second wiring portion 64b extending in the first direction at the second side of the diode pattern 14 to be electrically connected to a plurality of second through connectors 50b.

For example, the plurality of first through connectors 50a and the first wiring portion 64a may be electrically connected by a plurality of contact vias 62, respectively, each of the contact vias 62 overlapping a corresponding one of the first through connectors 50a and the first wiring portion 64a. Similarly, the plurality of second through connectors 50b and the second wiring portion 64b may be connected by a plurality of contact vias 62, respectively, each of the contact vias 62 overlapping a corresponding one of the second through connectors 50b and the second wiring portion 64b.

Because the plurality of first through connectors 50a and the plurality of second through connectors 50b are at opposite sides of the diode pattern 14, the first wiring portion 64a connected to the plurality of first through connectors 50a and the second wiring portion 64b connected to the plurality of second through connectors 50b may be at opposite sides of each other based on the diode pattern 14.

For example, the diode pattern 14, the first wiring portion 64a, and the second wiring portion 64b may each have a straight shape or a line shape extending in the first direction (X-axis direction in the drawing). Thus, a connection structure of the first wiring layer 64 connected to the through connector 50 may be simplified.

For example, the contact via 62 or the first wiring layer 64 included in the wiring portion 60 may include at least one of titanium, tungsten, nickel, cobalt, tantalum, molybdenum, copper, aluminum, gold, tin, manganese, ruthenium, beryllium, or an alloy thereof. Each first wiring layer 64 may include one layer or a plurality of layers.

For example, the first through connector 50a or the second through connector 50b included in the through connector 50 may include at least one of titanium, tungsten, nickel, cobalt, tantalum, molybdenum, copper, aluminum, gold, tin, manganese, ruthenium, beryllium, or an alloy thereof.

In an example embodiment, a side surface of the through connector 50 may have an inclined surface so that a width of the through connector 50 decreases as the through connector 50 goes from a front surface to a back surface. However, example embodiments are not limited thereto, and the side surface of the through connector 50 may have a vertical surface or other shapes.

For example, a length of the first conductive region 14a in the first direction may be greater than a width of the first through connector 50a in the first direction, and a length of the second conductive region 14b in the first direction may be greater than a width of the second through connector 50b in the first direction. A width of the first through connector 50a in the second direction may be greater than a width of the contact via 62 or the first wiring portion 64a connected to the first through connector 50a, and a width of the second through connector 50b in the second direction may be greater than a width of the contact via 62 or the second wiring portion 64b connected to the second through connector 50a. Accordingly, the first or second through connectors 50a and 50b may be stably formed and electrical connection properties may be improved, but example embodiments are not limited thereto. In some example embodiments, the length of the first or second conductive region 14a or 14b in the first direction may be equal to or less than the width of the first or second through connector 50a or 50b in the first direction. In some example embodiments, the width of the first or second through connector 50a or 50b in the second direction may be equal to or less than the width of the contact via 62 or the first or second wiring portion 64a or 64b connected to the first or second through connector 50a or 50b.

In an example embodiment, a side surface of the diode pattern 14 and a side surface of the through connector 50 may be connected to (e.g., in contact with) each other. More particularly, in the second direction, a first side surface 141 of the diode pattern 14 (e.g., the first conductive region 14a) and a side surface of the first through connector 50a may be connected to (e.g., in contact with) each other. Furthermore, in the second direction, a second side surface 142 of the diode pattern 14 (e.g., the second conductive region 14b) and a side surface of the second through connector 50b may be connected to (e.g., in contact with) each other. Accordingly, a current path may be effectively reduced.

A center of the first through connector 50a may be at a certain distance from a center of the diode pattern 14 in the second direction, and the side surface of the first through connector 50a may be in contact with the first side surface 141 of the first conductive region 14a. For example, in a plan view, a recess portion 14r may be provided on the first side surface 141 of the first conductive region 14a, and the first through connector 50a may fill the recess portion 14r. This is because a first through portion for forming the first through connector 50a is formed to overlap a portion of the first conductive region 14a, and then, the first through portion is filled with a metal material to form the first through connector 50a. That is, the first through connector 50a may be formed such that the recess portion 14r is provided on the first side surface 141 of the first conductive region 14a to stably connect the first side surface 141 of the first conductive region 14a and the side surface of the first through connector 50a.

Similarly, a center of the second through connector 50b is positioned at a certain distance from the center of the diode pattern 14 in the second direction, and the side surface of the second through connector 50b may be in contact with the second side surface 142 of the second conductive region 14b. For example, in a plan view, the recess portion 14r may be provided on the second side surface 142 of the second conductive region 14b, and the second through connector 50b may fill the recess portion 14r.

For example, a distance between the centers of the first or second through connectors 50a and 50b and the center of the diode pattern 14 in the second direction may be about 100 nm or less (e.g., about 1 nm to about 100 nm), but example embodiments are not limited thereto. In a case where connection between the first or second through connector 50a or 50b and the diode pattern 14 is maintained, a distance between the center of the first or second through connectors 50a and 50b and the center of the diode pattern 14 may exceed about 100 nm.

In this instance, a metal-semiconductor compound layer 14s may be at a boundary between the first side surface 141 of the first conductive region 14a and the side surface of the first through connector 50a. That is, the first through connector 50a may be electrically connected to the first conductive region 14a through the metal-semiconductor compound layer 14s. Similarly, the metal-semiconductor compound layer 14s may be at a boundary between the second side surface 142 of the second conductive region 14b and the side surface of the first through connector 50a. That is, the second through connector 50b may be electrically connected to the second conductive region 14b through the metal-semiconductor compound layer 14s.

The metal-semiconductor compound layer 14s may include a compound of metal and a semiconductor material included in the diode pattern 14. For example, the metal-semiconductor compound layer 14s may include metal silicide, for example, at least one of titanium silicide, tungsten silicide, nickel silicide, cobalt silicide, tantalum silicide, or molybdenum silicide. The metal included in the metal-semiconductor compound layer 14s may be the same as or different from a metal included in the through connector 50. As such, example embodiments are not limited to the above materials of the metal-semiconductor compound layer 14s.

The metal-semiconductor compound layer 14s at a boundary between the first side surface 141 of the first conductive region 14a and the side surface of the first through connector 50a and the metal-semiconductor compound layer 14s at a boundary between the second side surface 142 of the second conductive region 14b and the side surface of the second through connectors 50b may include same materials as each other. However, example embodiments are not limited thereto. The metal-semiconductor compound layer 14s at a boundary between the first side surface 141 of the first conductive region 14a and the side surface of the first through connector 50a and the metal-semiconductor compound layer 14s at a boundary between the second side surface 142 of the second conductive region 14b and the side surface of the second through connector 50b may include different materials.

The first semiconductor device 100 may form a pn diode. In this instance, the first semiconductor device 100 may have a bulk-less structure in which the diode pattern 14 is on the base insulating layer 10. The first semiconductor device 100 having the bulk-less structure may be provided in an integrated circuit together with a second semiconductor device 200 (refer to FIG. 3) having a backside power distribution network (BSPDN) structure. This will be described in more detail later with reference to FIGS. 3 and 4.

According to an example embodiment, the first semiconductor device 100 having the bulk-less structure may include the diode pattern 14, the through connector 50, and the wiring portion 60, and might not include a gate electrode 32a (refer to FIG. 3) and source and drain patterns 34 (refer to FIG. 3) included in the second semiconductor device 200. Thus, a structure may be simplified to have a short current path, and the diode pattern 14 and the through connection part 50 may have a sufficient connection area and thus resistance of the first semiconductor device 100 may be improved. Furthermore, the first semiconductor device 100 may be manufactured through an easy manufacturing process. Accordingly, performance and productivity of the first semiconductor device 100 may be improved.

In contrast, if a pn diode having a bulk-less structure includes a gate structure and source and drain patterns included in a second semiconductor device 200, a current path of the pn diode may include the source and drain patterns. Accordingly, the source and drain patterns may be on the current path of the pn diode, thereby increasing resistance due to resistance of the source and drain patterns. Furthermore, the pn diode and a wiring layer may be electrically connected through the source and drain patterns and a first contact portion connected to the source and drain patterns. Then, a connection area between the source and drain patterns and the first contact portion was small, and there was a limit to lowering resistance of the pn diode. Furthermore, tunneling leakage may occur due to a change in an energy band gap caused by a gate electrode. In order to reduce or prevent this issue, a process of replacing the gate electrode provided in the pn diode with an insulating layer may be performed, and then, a manufacturing process may be complicated.

As described above, the first semiconductor device 100 having the bulk-less structure may be provided in an integrated circuit together with the second semiconductor device 200 having the Backside Power Delivery Network (BSPDN) structure. The integrated circuit including the first semiconductor device 100 and the second semiconductor device 200 will be described with reference to FIGS. 3 and 4 along with FIGS. 1 and 2.

FIG. 3 is a cross-sectional view illustrating the first semiconductor device taken along a line X-X′ in FIG. 1 together with a second semiconductor device, and FIG. 4 is a cross-sectional view illustrating the first semiconductor device taken along a line Y-Y′ in FIG. 1 together with a second semiconductor device. The first semiconductor device is illustrated in (a) of FIG. 3 and (a) of FIG. 4, and the second semiconductor device is illustrated in (b) of FIG. 3 and (b) of FIG. 4. In this instance, FIG. 3 illustrates a cross section (XZ plane in the drawing) perpendicular to the second direction (Y-axis direction in the drawing), and FIG. 4 is a cross section (YZ plane in the drawing) perpendicular to the first direction (X-axis direction in the drawing). In FIG. 4B, source and drain patterns 34 are illustrated in a cross section (YZ plane of the drawing) perpendicular to the first direction (X-axis direction of the drawing), and a second wiring layer 66 and a third through connector 50c connected to the source and drain patterns 34 are conceptually illustrated.

Referring to FIGS. 3 and 4, in an example embodiment, the base insulating layer 10 may have a first area A1 and a second area A2. Herein, the first area A1 may refer to an area where the first semiconductor device 100 is positioned, and the second area A2 may refer to an area where the second semiconductor device 200 is positioned.

The base insulating layer 10 in the first area A1 and the second area A2 may include a same material. For example, the base insulating layer 10 in the first area A1 and the second area A2 may be a same layer formed through a same process. However, example embodiments are not limited thereto. In some example embodiments, the base insulating layer in the first area A1 and the base insulating layer in the second area A2 may include different materials or may be formed through different processes.

The above description may be applied to the first semiconductor device 100 in the first area A1.

The second semiconductor device 200 in second area A2 may include active patterns 16 and 26 on the base insulating layer 10, a gate structure 32, source and drain patterns 34, an insulating layer 40 (e.g., a second insulating layer 46), a through connector 50, a wiring portion 60, and a back wiring portion 70. In this instance, the back wiring portion 70 may include a back contact via 72 extending through the base insulating layer 10. As an example, the second semiconductor device 200 may have a bulk-less structure and a BSPDN structure.

The active patterns 16 and 26 may be on the base insulating layer 10. Portions of the active patterns 16 and 26 overlapping the gate structure 32 may form a channel region of a transistor.

The active patterns 16 and 26 may include a lower pattern 16 and a plurality of channel layers 26 on the lower pattern 16.

In an example embodiment, at least a partial portion (e.g., the lower pattern 16) of the active patterns 16 and 26 may have a shape that longitudinally extends along the first direction (X-axis direction in the drawing) on the base insulating layer 10. As an example, the plurality of channel layers 26 may be spaced apart from each other in the first direction. Furthermore, the active patterns 16 and 26 may be spaced apart from each other at regular intervals in the second direction (Y-axis direction in the drawing).

The plurality of channel layers 26 may be on the lower pattern 16 to be spaced apart from each other in a thickness direction (Z-axis direction in the drawing). Each of the plurality of channel layers 26 may have a channel pattern having a nanosheet shape with a thickness of nanometer level (e.g., 1 nm to 10 nm), and may be a semiconductor pattern containing a semiconductor material. The embodiments are not limited to thereto, and a shape of the channel layer 26 may be modified in various ways, and a thickness of the channel layer 26 may be less than 1 nm or greater than 10 nm.

The lower pattern 16 may include a crystalline semiconductor substrate (e.g., a single crystal semiconductor substrate or a polycrystalline semiconductor substrate) including a semiconductor material. In some example embodiments, the lower pattern 16 may include a crystalline semiconductor substrate (e.g., a single crystal semiconductor substrate or a polycrystalline semiconductor substrate) and an epitaxial layer grown from the crystalline semiconductor substrate and including a semiconductor material. The channel layers 26 may include an epitaxial layer including a semiconductor material.

For example, the semiconductor substrate provided in the lower pattern 16 may include at least one of a group IV semiconductor, a group III-V compound semiconductor, or a group II-VI compound semiconductor. For example, the semiconductor substrate provided in the lower pattern 16 may include at least one of Si, Ge, SiGe, SiC, GaAs, InAs, or InP. The semiconductor substrate and/or the epitaxial layer provided in the lower pattern 16 may include a same semiconductor material as the semiconductor substrate and/or the epitaxial layer provided in the diode pattern 14.

For example, the channel layers 26 may include at least one of a group IV semiconductor, a group III-V compound semiconductor, or a group II-VI compound semiconductor. In this instance, the channel layers 26 may include at least one of Si, Ge, SiGe, SiC, GaAs, InAs, or InP, for example, at least one of Si, Ge, or SiGe. Each of the channel layers 26 may include a same material as the lower pattern 16 or a different material from the lower pattern 16.

For example, the lower pattern 16 and the channel layers 26 may include Si or SiGe. In some example embodiments, the lower pattern 16 may include Si, and the channel layers 26 may include SiGe. Numerous other variations are possible.

A material of the lower pattern 16, a shape, a thickness, or a material of the channel layer 26, or a number of channel layers 26 constituting one channel structure may be changed in various ways.

The gate structure 32 may cross the active patterns 16 and 26 and may extend in the second direction (Y-axis direction in the drawing). A plurality of gate structures 32 may be spaced apart from each other in the first direction (X-axis direction in the drawing).

The gate structure 32 may include a gate electrode 32a, a gate insulating layer 32b, a gate spacer 32c, and a gate capping layer 32d.

The gate electrode 32a may be on the active patterns 16 and 26 including the plurality of channel layers 26 while entirely surrounding each of the plurality of channel layers 26. The gate electrodes 32a may be separated from each other in the second direction (Y-axis direction in the drawing) depending on a circuit configuration of the first semiconductor device 100. For example, the gate electrode 32a may be separated into a plurality of gate electrodes 32a in the second direction by a separate gate separation portion (not shown) in the gate electrode 32a.

A gate insulating layer 32b may be between the gate electrode 32a and the channel layers 26. In an example embodiment, the gate insulating layer 32b may be between the active patterns 16 and 26 and the gate electrode 32a, and may be further between the gate electrode 32a and the gate spacer 32c.

The gate spacer 32c may be on a side surface of the gate electrode 32a to insulate the gate electrode 32a from the source and drain pattern 34 and/or a first contact portion 52. For example, the gate spacer 32c may be on the side surface of the gate electrode 32a at the upper portion of the active patterns 16 and 26, but might not be on a side surface of the channel layer 26 that constitutes the active patterns 16 and 26. The gate spacer 32c may extend in the second direction (Y-axis direction in the drawing) at both side surfaces of the gate electrode 32a in the first direction (X-axis direction in the drawing).

A gate capping layer 32d may be on the gate electrode 32a. In FIG. 2, it is illustrated that the gate spacer 32c is on a side surface of the gate capping layer 32d. In some example embodiments, the gate capping layer 32d may be on the gate spacer 32c. In an example embodiment, a front surface of the gate capping layer 32d may be on a same plane as a front surface of the first contact portion 52 or the insulating layer 40. However, example embodiments are not limited thereto. Accordingly, the front surface of the gate capping layer 32d may be on a different plane from the front surface of the first contact portion 52 or the insulating layer 40.

The gate electrode 32a may include a conductive material. For example, the gate electrode 32a may include at least one of metal, a metal alloy, metal nitride, metal silicide, or a doped semiconductor material. Here, the metal or the metal alloy included in the gate electrode 32a may include at least one of tungsten, molybdenum, aluminum, copper, or cobalt, and the metal nitride included in the gate electrode 32a may include at least one of tungsten nitride, molybdenum nitride, titanium nitride, or tantalum nitride. The gate electrode 32a may further include an oxidized metal oxide or a metal oxynitride including the above material, or the gate electrode 32a may include a plurality of layers.

The gate insulating layer 32b may include oxide, nitride, or a high dielectric constant material. The high dielectric constant material may refer to a dielectric material having a higher dielectric constant than the silicon oxide. For example, the gate insulating layer 32b may include at least one of silicon oxide, silicon nitride, silicon oxynitride, hafnium oxide layer, aluminum oxide layer, or tantalum oxide layer. The gate insulating layer 32b may include a plurality of insulating layers.

The gate spacer 32c may include at least one of silicon oxide, silicon nitride, or silicon oxynitride, or may further include carbon. For example, the gate spacer 32c may include a low dielectric constant material. The gate spacer 32c may include a plurality of layers. The gate capping layer 32d may include at least one of silicon oxide, silicon nitride, or silicon oxynitride.

However, example embodiments are not limited to the above, and the gate electrode 32a, the gate insulating layer 32b, the gate spacer 32c, or the gate capping layer 32d may include any of various materials or may have any of various structures.

Source and drain patterns 34 may be at both sides of the active patterns 16 and 26 and/or the gate structure 32. In this instance, the source and drain patterns 34 may be adjacent to the both sides of the active patterns 16 and 26 in the first direction (X-axis direction in the drawing), and may constitute a source region or a drain region of a transistor.

The source and drain patterns 34 may include an epitaxial layer formed through a selective epitaxial growth (SEG) process at a portion where the active patterns 16 and 26 are recessed. The source and drain patterns 34 may have an angular shape, but example embodiments are not limited thereto, and may have various shapes such as polygon, circular, oval, and round shapes.

For example, the source and drain patterns 34 may include at least one of Si, Si—Ge, or SiC, and may further include dopants such as arsenic (As) or phosphorus (P). In some example embodiments, the source and drain patterns 34 may include a plurality of portions having different materials or different compositions. However, example embodiments are not limited to the above, and the source and drain patterns 34 may include any of various materials or have any of various structures.

The insulating layer 40 (e.g., a second insulating layer 46) covering at least partial portions of the active patterns 16 and 26 and the source and drain patterns 34 may be on the base insulating layer 10.

For example, the second insulating layer 46 may include a third insulating portion 46a and a fourth insulating portion 46b. The third insulating portion 46a may be on the base insulating layer 10, and the fourth insulating portion 46b may be between the source and drain patterns 34 and the through connector 50. The fourth insulating portion 46b may be a diffusion break, e.g., a single diffusion break (SDB). A boundary between the third insulating portion 46a and the fourth insulating portion 46b may be seen or might not be clearly seen. In some example embodiments, an etch stop layer (not illustrated) may be provided between the source and drain patterns 34 and the second insulating layer 46.

The third insulating portion 46a or the fourth insulating portion 46b may include one layer or a plurality of layers. The plurality of layers included in the third insulating portion 46a or the fourth insulating portion 46b may include a same material or different materials. A boundary between the plurality of layers included in the third insulating portion 46a or the fourth insulating portion 46b may be seen or might not be clearly seen. The third insulating portion 46a and the fourth insulating portion 46b may have a same material or different materials. For example, the third insulating portion 46a or the fourth insulating portion 46b may include at least one of silicon oxide, silicon nitride, silicon oxynitride, or a low dielectric constant material. However, example embodiments are not limited to the above, and the third insulating portion 46a or the fourth insulating portion 46b may include any of various materials or have any of various structures.

The second insulating layer 46 (e.g., the third insulating portion 46a or the fourth insulating portion 46b) and the first insulating layer 44 (e.g., the first insulating portion 44a or the second insulating portion 44b) may include a same material as each other, or may include different materials.

The wiring portion 60 on the second insulating layer 46 in the second area A2 may include a second wiring layer 66 along with the contact via 62 and the upper insulating layer 68. For the contact via 62 and the upper insulation layer 68, the above description of the contact via 62 and the upper insulating layer 68 included in the wiring portion 60 on the first insulating layer 44 in the first area A1 may be applied.

For simple illustration and a clear understanding, it is illustrated in the drawing that the second wiring layer 66 includes a first layer connected to the through connector 50 through the contact via 62. However, example embodiments are not limited thereto. The second wiring layer 66 may further include one or more additional wiring layers connected to the first layer through a contact via with an insulating layer provided therebetween.

In this instance, the first contact portion 52 may extend through the second insulating layer 46 to electrically connect the source and drain patterns 34 and the second wiring layer 66. For example, the first contact portion 52 may be in contact with the source and drain patterns 34 and the contact via 62. The second contact portion 54 may extend through the first upper insulating layer 68a, the second insulating layer 46, and the gate capping layer 32d to electrically connect the gate electrode 32a and the second wiring layer 66. For example, the second contact portion 54 may be in contact with the gate electrode 32a and the contact via 62.

The first or second contact portion 52 or 54 may include a single layer or a plurality of layers. The first or second contact portion 52 or 54 may include various conductive materials. For example, the first or second contact portion 52 or 54 may include at least one of metal, a metal alloy, metal nitride, metal silicide, or a doped semiconductor material. Here, the metal or the metal alloy included in the first or second contact portion 52 or 54 may include at least one of titanium, tungsten, nickel, cobalt, tantalum, molybdenum, copper, aluminum, gold, tin, manganese, ruthenium, or beryllium, or an alloy thereof. The metal nitride included in the first or second contact portion 52 or 54 may include at least one of titanium nitride, tungsten nitride, tantalum nitride, or molybdenum nitride. The first or second contact portion 52 or 54 may further include oxidized metal oxide or metal nitride including the above-described metal oxide or metal nitride. According to some example embodiments, the first or second contact portion 52 or 54 may include a plurality of layers. However, example embodiments are not limited to the above, and the first or second contact portion 52 or 54 may include any of various materials or may have any of various structure.

The through connector 50 may be at a periphery of the source and drain patterns 34 to extend through the insulating layer 40 (e.g., the second insulating layer 46) and electrically connect the source and drain patterns 34 and the back wiring portion 70 via the wiring portion 60. For example, the through connector 50 may be in contact with the contact via 62 and the back contact via 72 to connect the contact via 62 and the back contact via 72. In the drawing, it is illustrated that the through connector 50 in the second area A2 includes the third through connector 50c at one side of the source and drain patterns 34 with the fourth insulating portion 46b therebetween, but example embodiments are not limited thereto.

The third through connector 50c may be at a periphery of the source and drain patterns 34 and spaced apart from the source and drain patterns 34. The third through connector 50c may be connected to the source and drain patterns 34 through the wiring portion 60.

The third through connector 50c may be spaced apart from the source and drain patterns 34 at a certain distance. In some example embodiments, the fourth insulating portion 46b may be between the third through connector 50c and the source and drain patterns 34 in the first direction. For example, the third through connector 50c may include at least one of titanium, tungsten, nickel, cobalt, tantalum, molybdenum, copper, aluminum, gold, tin, manganese, ruthenium, beryllium, or an alloy thereof.

The third through connector 50c may include a same material as the first or second through connector 50a or 50b, or may include different materials from each other.

The second semiconductor device 200 may include the back wiring portion 70 at a side where the base insulating layer 10 is formed (more particularly, at a back surface). The back wiring portion 70 may include the back contact via 72 extending through the base insulating layer 10.

The back wiring portion 70, which is a portion of the BSPDN structure that provides power to the second semiconductor device 200, may be included separately from the wiring portion 60 at a front surface of the second semiconductor device 200.

The back wiring portion 70 may include a back contact via 72, a back wiring layer 76, and a back insulating layer 78. The back contact via 72 may extend through the base insulating layer 10 to be connected to the third through connector 50c. Accordingly, the power provided through the back wiring layer 76 may be provided to source and drain patterns 34 via the back contact via 72, the third through connector 50c, the contact via 62, the second wiring layer 66, the contact via 62, and the first contact portion 52.

For simple illustration and a clear understanding, it is illustrated in the drawing that the back wiring layer 76 includes a first layer connected to the through connector 50 through the back contact via 72. However, example embodiments are not limited thereto. The back wiring layer 76 may further include one or more additional wiring layers connected to the first layer through a contact via with an insulating layer provided therebetween.

For example, the back contact via 72 or the back wiring layer 76 included in the back wiring portion 70 may include at least one of titanium, tungsten, nickel, cobalt, tantalum, molybdenum, copper, aluminum, gold, tin, manganese, ruthenium, beryllium, or an alloy thereof. Each back wiring layer 76 may include one layer or a plurality layers. The back insulating layer 78 may include at least one of silicon oxide, silicon nitride, silicon oxynitride, or a low dielectric constant material. However, example embodiments are not limited to the above, and the back insulating layer 78 may include any of various materials or have any of various structures.

In an example embodiment, a side surface of the back contact via 72 may have an inclined surface such that a width of the back contact via 72 increases from a front surface (e.g., top or upper end) toward a back surface (e.g., bottom or lower end).

In the drawing, it is illustrated that the back insulating layer 78 is at a lower portion of the base insulating layer 10 in the first area A1, but example embodiments are not limited thereto. The back insulating layer 78 might not be at the lower portion of the base insulating layer 10 in the first area A1. Numerous other variations are possible.

According to an example embodiment, the first semiconductor device 100 having the bulk-less structure and the second semiconductor device 200 having the BSPDN structure have electrical connection structures by the through connector 50. Accordingly, the electrical connection structure may be simplified. That is, a structure of the integrated circuit including the first semiconductor device 100 having the bulk-less structure and the second semiconductor device 200 having the BSPDN structure may be simplified, and the integrated circuit may be formed through an easy manufacturing process.

The above second semiconductor device 200 may be an example, and example embodiments are not limited thereto. That is, in the above description and drawings, the second semiconductor device 200 has been illustrated with a gate-all-around (GAA) structure or a multi-bridge-channel (MBC) structure in which the four surfaces of the channel layer 26 are surrounded by the gate electrode 32a. However, example embodiments are not limited thereto, and the second semiconductor device 200 may have a finFET structure, a 3D stack field effect transistor (3DSFET) structure, or a complementary field effect transistor (CFET) structure. Numerous other variations are possible.

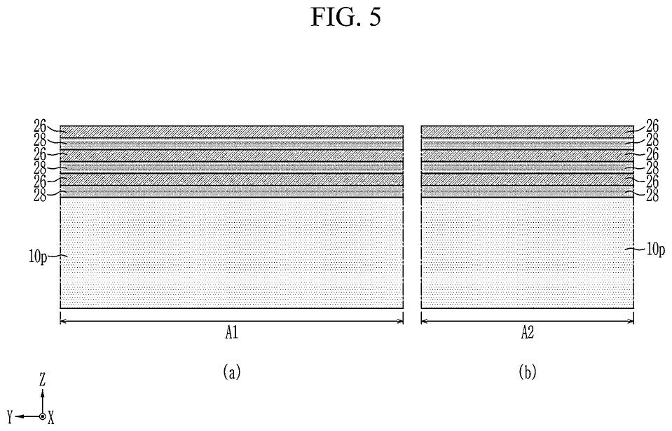

A manufacturing method for the first semiconductor device 100 (refer to FIG. 1) having the bulk-less structure will be described in detail with reference to FIGS. 5 to 17. As described above, the first semiconductor device 100 together with a second semiconductor device 200 (refer to FIG. 3) having a BSPDN structure forms an integrated circuit. Hereinafter, a manufacturing method of the first semiconductor device 100 will be described while describing a manufacturing method of the integrated circuit including the first semiconductor device 100 and the second semiconductor device 200.

FIG. 5 to FIG. 17 are cross-sectional views illustrating a manufacturing method for an integrated circuit including a first semiconductor device according to an example embodiment.

As illustrated in FIGS. 5 and 6, a semiconductor substrate 10p and a stacked structure 20 for forming a first semiconductor device 100 and a second semiconductor device 200 may be formed. FIGS. 5 and 6 illustrate portions corresponding to FIG. 4.

As illustrated in FIG. 5, a plurality of sacrificial layers 28 and a plurality of channel layers 26 may be formed alternately on the semiconductor substrate 10p.

The semiconductor substrate 10p may be a bulk substrate including a semiconductor material or a semiconductor-on-insulator. For example, the semiconductor substrate 10p may include at least one of a group IV semiconductor, a group III-V compound semiconductor, or a group II-VI compound semiconductor. For example, the semiconductor substrate 10p may include at least one of Si, Ge, SiGe, SiC, GaAs, InAs, or InP. For example, the semiconductor-on-insulator may be a silicon-on-insulator (SOI) or a silicon-germanium-on-insulator (SGOI).

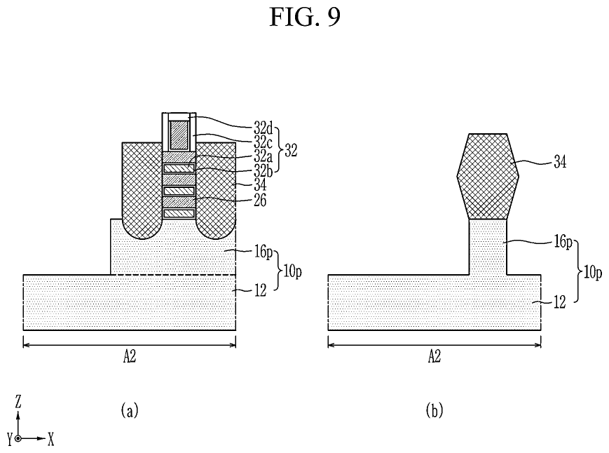

The channel layers 26 and the sacrificial layers 28 may be formed by epitaxial growth. The channel layer 26 may include a semiconductor material. The sacrificial layer 28 may be removed in a later process to provide a space where a gate insulating layer 32b (refer to FIG. 9) and a gate electrode 32a (refer to FIG. 9) are positioned. The sacrificial layer 28 may include a material having etch selectivity to the channel layer 26 with respect to an etching material that etches the channel layer 26. For example, the channel layer 26 may include Si, and the sacrificial layer 28 may include SiGe. However, the channel layer 26 or the sacrificial layer 28 may include any of various materials.

As illustrated in FIG. 6, the stacked structure 20 and the semiconductor substrate 10p including a bulk portion 12 and pattern portions 14p and 16p may be formed by forming a trench 20t where the channel layers 26, the sacrificial layers 28, and the semiconductor substrate 10p are partially removed.

In a plan view, each trench 20t may extend in the first direction (X-axis direction in the drawing), and a plurality of trenches 20t may be spaced apart from each other at regular intervals in the second direction (Y-axis direction in the drawing). In a cross-sectional view, the trench 20t may entirely remove the channel layers 26 and the sacrificial layers 28 and may partially remove the semiconductor substrate 10p in the third direction (Z-axis direction in the drawing).

The bulk portion 12 of the semiconductor substrate 10p may be a portion where the trench 20t is not formed. The bulk portion 12 of the semiconductor substrate 10p may have a desired (or alternatively, predetermined) thickness in the third direction (Z-axis direction in the drawing), and may have an area connected as a whole to have a plane (XY plane in the drawing) with a desired (or alternatively, predetermined) size in the first direction (X-axis direction in the drawing) and the second direction (Y-axis direction in the drawing) in a plan view. In a plan view, each of the pattern portions 14p and 16p may extend in the first direction (X-axis direction in the drawing), and a plurality of pattern portions 14p and 16p may be spaced apart from each other at regular intervals in the second direction (Y-axis direction in the drawing). In a cross-sectional view, the pattern portions 14p and 16p of the semiconductor substrate 10p may have a shape that partially protrudes upwards from an upper portion of the bulk portion 12 in the third direction (Z-axis direction in the drawing).

The pattern portions 14p and 16p may constitute a diode pattern 14 (refer to FIG. 1) included in the first semiconductor device 100 in the first area A1, and a lower pattern 16 (refer to FIG. 1) of an active pattern included in the second semiconductor device 200 in the second area A2.

The diode pattern 14 may include a first conductive region 14a (refer to FIG. 1) and a second conductive region 14b (refer to FIG. 1) adjacent to each other in the first direction (X-axis direction in the drawing). The lower pattern 16 may include a region having a first conductivity type or a region having a second conductivity type. The first conductive region 14a, the second conductive region 14b, the region having the first conductivity type, and the region having the second conductivity type may be provided on the semiconductor substrate 10p before forming the trench 20t (e.g., before forming the sacrificial layers 28 and the channel layers 26).

The stacked structure 20 may include a plurality of sacrificial layers 28 and a plurality of channel layers 26 on the pattern portions 14p and 16p of the semiconductor substrate 10p. The stacked structure 20 may be on an upper portion of the pattern portions 14p and 16p in the third direction (Z-axis direction in the drawing). In a plan view, each stacked structure 20 may extend in the first direction (X-axis direction in the drawing), and a plurality of stacked structures 20 may be spaced apart from each other at regular intervals in the second direction (Y-axis direction in the drawing).

The trench 20t may be formed by an etching process performed from a front surface (e.g., top surface) of the stacked structure 20 including the plurality of sacrificial layers 28 and the plurality of channel layers 26. However, example embodiments are not limited thereto, and a formation process of the trench 20t, the pattern portions 14p and 16p, or the stacked structure 20 may be modified in various ways.

As described above, the semiconductor substrate 10p and the stacked structure 20 for forming the first semiconductor device 100, which is a diode device, and the second semiconductor device 200, which is a transistor device, are formed together, and thus, the stacked structure 20 may be provided on the diode pattern 14.

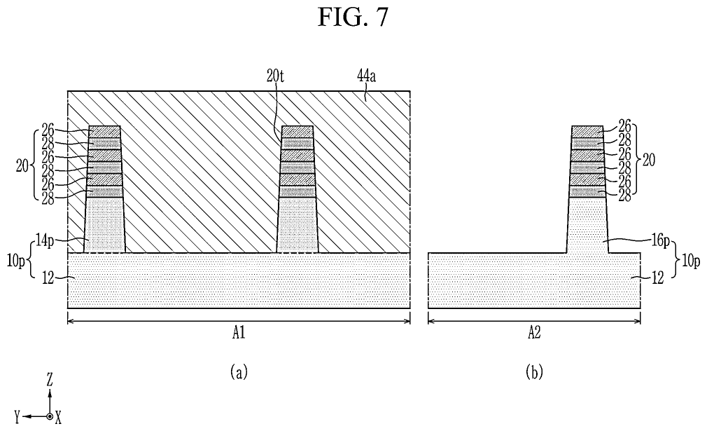

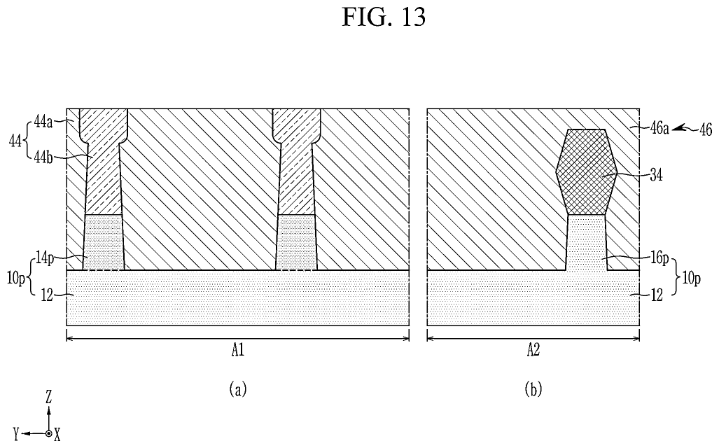

Subsequently, as illustrated in FIG. 7, a first insulating portion 44a of a first insulating layer 44 (refer to FIG. 13) may be formed in the first area A1. FIG. 7 illustrates a portion corresponding to FIG. 4.

In an example embodiment, the first insulating portion 44a in the first area A1 may fill the trench 20t on the semiconductor substrate 10p and the stacked structure 20. A front surface (e.g., top surface) of the first insulating portion 44a may be positioned higher than a front surface (e.g., top surface) of the stacked structure 20. In some example embodiments, the front surface of the first insulation portion 44a may be positioned on a same plane as the front surface of the stacked structure 20.

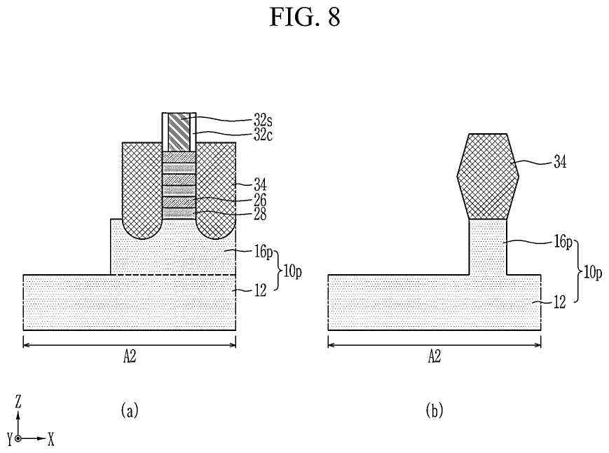

In this instance, the first insulating portion 44a might not be formed in the second area A2, and thus the semiconductor substrate 10p and the stacked structure 20 in the second area A2 may be exposed. Accordingly, as illustrated in FIGS. 8 and 9, a portion included in the second semiconductor device 200 may be formed in the second area A2 while the first insulating portion 44a protects the diode pattern 14 (refer to FIG. 1) or the pattern portion 14p in the first area A1.

For example, the first insulating portion 44a that covers the first area A1 while exposing the second area A2 may be the first insulating portion 44a in the first semiconductor device 100. Accordingly, the manufacturing process may be easily performed by using the first insulating portion 44a covering the first area A1 as it is. However, example embodiments are not limited thereto. In some example embodiments, at least a portion of the insulating layer covering the first area A1 while exposing the second area A2 may be replaced with another insulating layer to form the first insulating portion 44a in the first semiconductor device 100.

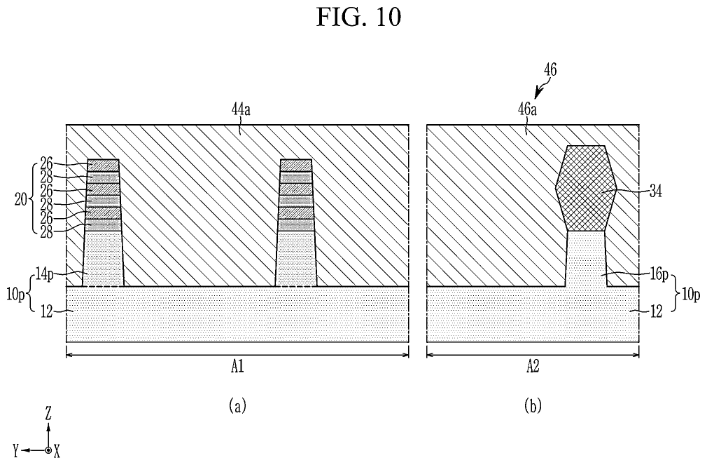

Subsequently, as illustrated in FIGS. 8 to 10, a gate structure 32, source and drain patterns 34, and a third insulating portion 46a of the second semiconductor device 200 may be formed in the second area A2. For a clear understanding and brief description, FIGS. 8 and 9 mainly illustrate the gate structure 32 and the source and drain patterns 34. (a) of FIG. 8 and (b) of FIG. 9 illustrate portions corresponding to (b) of FIG. 3, and (b) of FIG. 8 and (b) of FIG. 9 illustrate portions corresponding to (b) of FIG. 4). FIG. 10 illustrates a portion corresponding to FIG. 4.

As illustrated in FIG. 8, a dummy gate 32s may be formed on the active patterns 16 and 26. The dummy gate 32s may be a layer that is replaced with a gate electrode 32 (refer to FIG. 9) in a later process. For example, the dummy gate 32s may include polycrystalline silicon, but example embodiments are not limited thereto. In some example embodiments, a gate spacer 32c may be further formed at both sides of the dummy gate 32s. In an example embodiment, the dummy gate 32s and/or the gate spacer 32c may extend in a direction intersecting an extension direction of the active patterns 16 and 26. For example, the dummy gate 32s and/or the gate spacer 32c may extend in the second direction (Y-axis direction in the drawing), and a plurality of dummy gates 32s and/or a plurality of gate spacers 32c may be spaced apart from each other in the first direction (X-axis direction in the drawing).

The stacked structure 20 may be etched by an etching process using the dummy gate 32s and/or the gate spacer 32c as a mask, and the lower pattern 16 may be exposed at an outside of the dummy gate 32s and the gate spacer 32c. In some example embodiments, a portion of the sacrificial layer 28 exposed at side surfaces of the dummy gate 32s and the gate spacer 32c is removed to form an inner spacer space, and an inner spacer (not illustrated) may be formed by filling the inner spacer space with an insulating material. The inner spacer may include a same material as the gate spacer 32c, but example embodiments are not limited thereto.

The source and drain patterns 34 may be formed from the front surface of the exposed lower pattern 16 using a selective epitaxial growth process. A thickness of the source and drain patterns 34 may vary. For example, the front surface (e.g., top surface) of the source and drain patterns 34 may be positioned higher than the front surfaces (e.g., top surfaces) of the active patterns 16 and 26, or the front surfaces of the source and drain patterns 34 and the front surface of the active patterns 16 and 26 may be positioned on a same plane.

As illustrated in FIG. 9, the gate structure 32 may be formed by replacing the dummy gate 32s (refer to FIG. 8) with a gate electrode 32a.

For example, the dummy gate 32s may be removed using an etching material capable of selectively etching the dummy gate 32s without etching the source and drain patterns 34 and the gate spacer 32c. When the dummy gate 32s is removed, the channel layer 26 and the sacrificial layer 28 (refer to FIG. 8) at a lower portion of the dummy gate 32s may be exposed to an outside. The sacrificial layer 28 exposed to the outside may be selectively removed using an etching process.

A gate insulating layer 32b and a gate electrode 32a may be formed in a space where the sacrificial layer 28 has been removed. The gate insulating layer 32b may be formed conformally on a surface exposed by the space where the sacrificial layer 28 was removed. The gate electrode 32a may be formed to fill the space on the gate insulating layer 32b. The gate insulating layer 32b or the gate electrode 32a may be formed by using an atomic layer deposition (ALD) process, a chemical vapor deposition (CVD) process, or the like. A gate capping layer 32d may be formed on the gate insulating layer 32b and/or the gate electrode 32a on the active patterns 16 and 26.

As illustrated in FIG. 10, a third insulating portion 46a may be formed to cover the gate structure 32 and the source and drain patterns 34 on the semiconductor substrate 10p. In FIGS. 9 and 10, it is illustrated that the third insulating portion 46a is formed after forming the source and drain patterns 34. In some example embodiments, a partial portion of the third insulating portion 46a may be formed before forming the source and drain patterns 34. In this instance, the source and drain patterns 34 may be grown and formed in a space between the third insulating portions 46a. However, example embodiments are not limited thereto, and process orders of the source and drain pattern 34 and the third insulation portion 46a may be modified in various ways. Numerous other variations are possible.

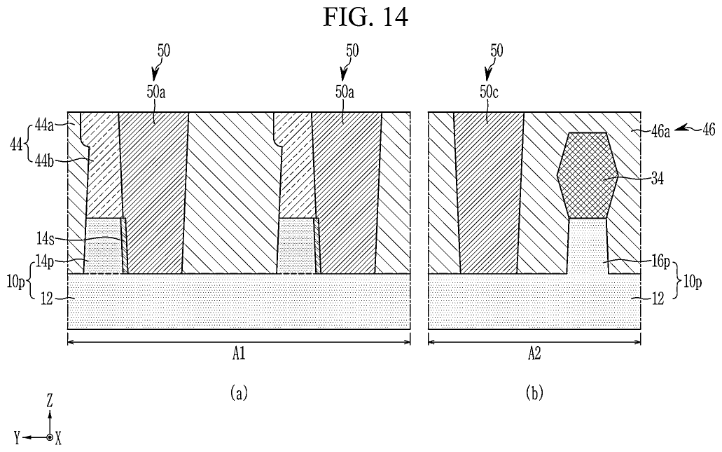

In some example embodiments, a fourth insulating portion 46b (refer to FIG. 3) including a portion between a third through connector 50c (refer to FIG. 14) and the source and drain patterns 34 may be formed in the second area A2. The fourth insulating portion 46b may be formed before forming the third through connector 50c. Thereby, the second insulating layer 46 may be formed.

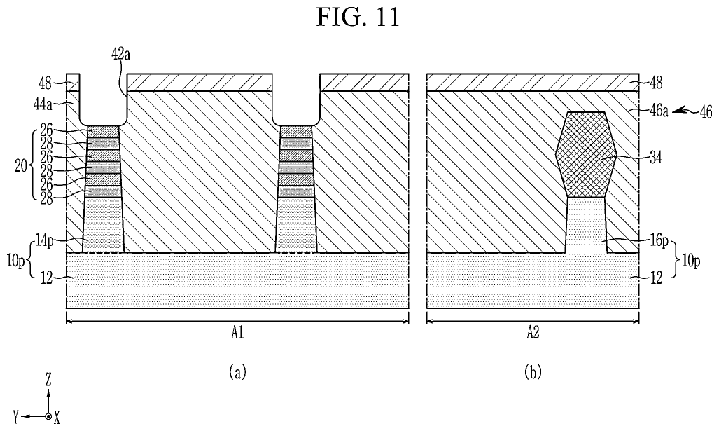

Subsequently, as illustrated in FIGS. 11 to 13, the stacked structure 20 in the first area A1 may be removed and a second insulating portion 44b may be formed on the diode pattern 14 (refer to FIG. 1) or the pattern portion 14p. FIGS. 11 to 13 illustrate portions corresponding to FIG. 4.

As illustrated in FIG. 11, a first opening 42a expose the stacked structure 20 may be formed in the first area A1.

For example, a mask layer 48 may be disposed on the first insulating portion 44a to expose a portion of the first area A1 where the stacked structure 20 is positioned. For example, the mask layer 48 may be formed through a photo lithography process, but example embodiments are not limited thereto. The first opening 42a may be formed by removing a partial portion of the first insulating portion 44a located at the top of the stacked structure 20 through an etching process performed from a front surface using the mask layer 48. As the etching process, dry etching or wet etching may be applied.

In an example embodiment, in the second direction (Y-axis direction of drawing), a width of the first opening 42a may be greater than a width of the stacked structure 20 in the first region A1. Accordingly, the stacked structure 20 may be stably removed in a removal process of the stacked structure 20 which will be performed later through the first opening 42a. However, example embodiments are not limited thereto. In the second direction, the width of the first opening 42a may be equal to or less than the width of the stacked structure 20 in the first area A1.

As illustrated in FIG. 12, a second opening 42b may be formed by removing the stacked structure 20 (refer to FIG. 11) through the first opening 42a. Thus, an opening 42c including the first opening 42a and the second opening 42b may be formed.

A process of removing the stacked structure 20 may be performed using an etching process capable of selectively etching the stacked structure 20. For example, the process of removing the stacked structure 20 may be performed by a dry etching process or a wet etching process. The etching process might not proceed smoothly in an area where the first insulating portion 44a is positioned, the first insulating portion 44a may act as a kind of etch stop surface. Accordingly, the stacked structure 20 may be selectively removed. However, example embodiments are not limited thereto.

The mask layer 48 may be removed after forming the opening 42c. In FIGS. 12 and 13, it is illustrated that the mask layer 48 is removed before forming the second insulating portion 44b (refer to FIG. 13), but example embodiments are not limited thereto. In some example embodiments, the mask layer 48 may be removed in a chemical mechanical polishing process performed in the process of forming the second insulating portion 44b or in a subsequent process.

As illustrated in FIG. 13, the second insulating portion 44b may be formed to fill the opening 42c. The second insulating portion 44b may be formed by forming an insulating material to fill the opening 42c and then performing a chemical-mechanical polishing process to be flush with the front surface (e.g., top surface) of the first insulating portion 44a. Thereby, the first insulating layer 44 may be formed.

Subsequently, as illustrated in FIG. 14, a through connector 50 may be formed in the first area A1. In this instance, the through connector 50 may be formed in the second area A2 as well. For example, a first through connector 50a and a second through connector 50b may be formed in the first area A1, and a third through connector 50c may be formed in the second area A2.

In an example embodiment, a first through portion, a second through portion, and a third through portion may be formed to correspond to the first through connector 50a, the second through connector 50b, and the third through connector 50c, respectively. The first to third through portions may be formed through various etching processes (e.g., dry etching processes).

In an example embodiment, a metal-semiconductor compound layer 14s may be formed on a first side surface of the first conductive region 14a exposed through the first through portion and on a second side surface of the second conductive region 14b exposed through the second through portion after forming the first to third through portions. For example, a metal layer may be formed on the first side surface of the first conductive region 14a and the second side surface of the second conductive region 14b and heat-treated to form the metal-semiconductor compound layer 14s. However, example embodiments are not limited thereto. In some example embodiments, the metal-semiconductor compound layer 14s may be formed through heat treatment in a subsequent process without performing heat treatment after forming the metal layer. In some example embodiments, a process of forming the metal-semiconductor compound layer 14s might not be performed separately. In this instance, through the heat treatment process performed in the subsequent process, a semiconductor material of the first or second conductive region 14a or 14b and metal of the first or second through connector 50a or 50b may be chemically bonded to each other, thereby forming the metal-semiconductor compound layer 14s.

The first through connector 50a, the second through connector 50b, and the third through connector 50c may be formed by filling a conductive material in the first through portion, the second through portion, and the third through portion, respectively. After filling the conductive material, a planarization process may be performed so that a front surface (e.g., top surface) of the conductive material is flush with the front surface of the insulating layer 40. The planarization process may be performed, for example, by chemical mechanical polishing.

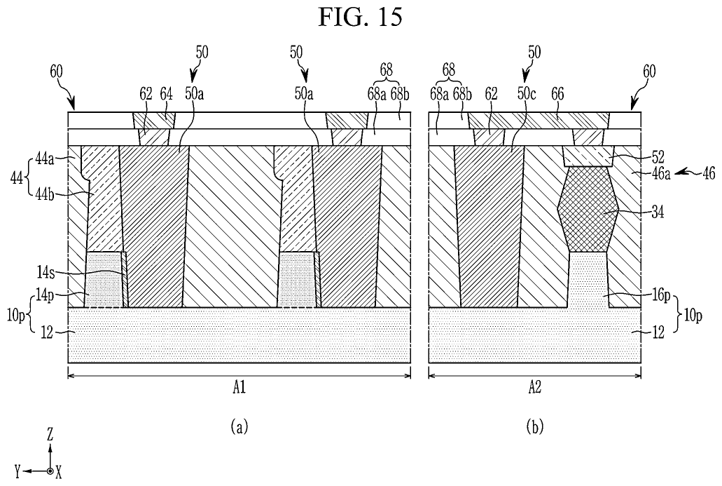

Subsequently, as illustrated in FIG. 15, a first contact portion 52, a second contact portion 54 (refer to FIG. 3), and a wiring portion 60 may be formed.

For example, the first contact portion 52 electrically connected to the source and drain patterns 34 may be formed in the second area A2. The first contact portion 52 electrically connected to the source and drain patterns 34 may be formed by forming a contact hole exposing the source and drain patterns 34 through the second insulating layer 46 in the second area A2 and then filling the contact hole with a conductive material.

Furthermore, a first upper insulating layer 68a may be formed on the insulating layer 40 and the first contact portion 52.

A contact hole that extends through the first upper insulating layer 68a and exposes the through connector 50 may be formed. For example, first and second contact holes may be formed in the first area A1 through the first upper insulating layer 68a to expose the first and second through connectors 50a and 50b, and a third contact hole may be formed in the second area A2 through the first upper insulating layer 68a to expose the third through connector 50c. The first to third contact holes may be filled with a conductive material to form contact vias 62 connected to the through connectors 50, respectively.

A contact hole may be formed through the first upper insulating layer 68a, the second insulating layer 46, and the gate capping layer 32d to expose the gate electrode 32a, and the second contact portion 54 connected to the gate electrode 32a may be formed by filling the contact hole with a conductive material.

A process order of the contact via 62 and the second contact portion 54 may be modified in various ways. That is, the second contact portion 54 may be formed after forming the contact via 62, the contact via 62 may be formed after forming the second contact portion 54, and the contact via 62 and the second contact portion 54 may be formed together.

Furthermore, a first wiring layer 64, a second wiring layer 66, and a second upper insulating layer 68b may be formed on the first upper insulating layer 68a. Thereby, the wiring portion 60 may be formed.

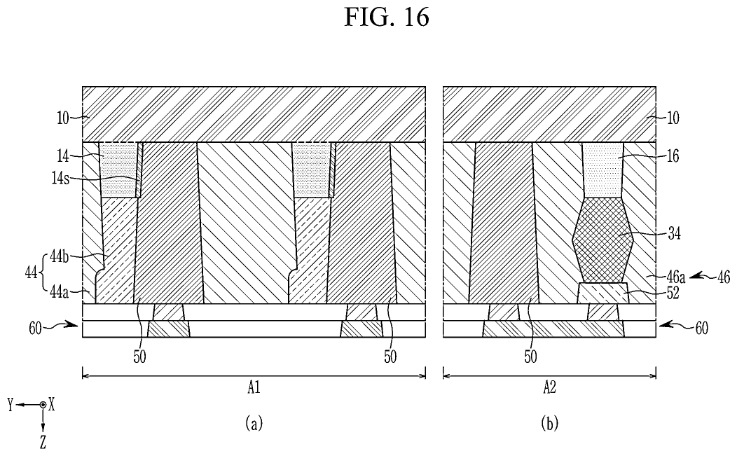

Subsequently, as illustrated in FIG. 16, in a state that a back surface of the semiconductor substrate 10p (refer to FIG. 15) positioned at an upper portion, a bulk portion 12 (refer to FIG. 15) of the semiconductor substrate 10p may be removed and a base insulating layer 10 may be formed.

A process of removing the bulk portion 12 of the semiconductor substrate 10p may be performed by an etching process using an etching material capable of selectively etching the semiconductor substrate 10p. In this instance, the etching process might not proceed smoothly in an area where the first or second insulating layers 44 or 46 is disposed, and thus, the back surface of the first or second insulating layer 44 or 46 may act as a kind of etch stop surface. Accordingly, the bulk portion 12 of the semiconductor substrate 10p may be stably removed up to the back surface of the first or second insulation layer 44 or 46. However, example embodiments are not limited thereto. A process of removing the bulk portion 12 of the semiconductor substrate 10p may be performed by at least one of a wet etching process or a polishing process (e.g., a chemical mechanical polishing (CMP) process). Numerous other variations are possible.

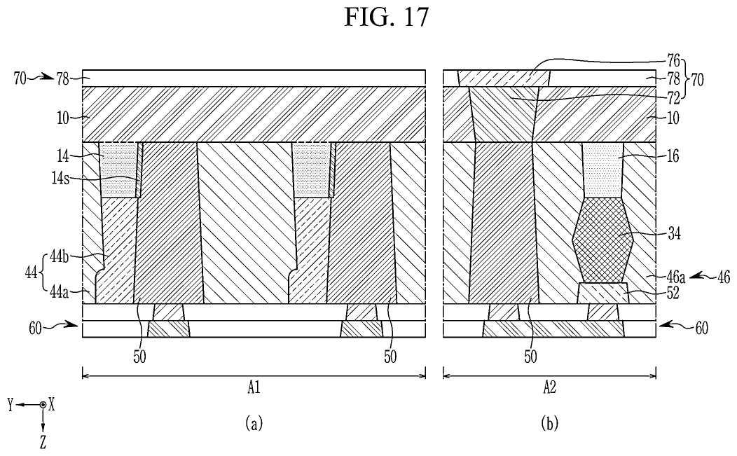

Subsequently, as illustrated in FIG. 17, a back wiring portion 70 including a back contact via 72 extending through the base insulating layer 10 may be formed in the second area A2.

For example, a contact opening may be formed in the base insulating layer 10 to expose the through connector 50 (e.g., the third through connector 50c) in the second area A2, and the back contact via 72 may be formed by filling the contact opening with a conductive material. For example, a planarization process may be performed after filling the contact opening with the conductive material. The planarization process may be performed, e.g., by a chemical mechanical etching process.

A back wiring layer 76 and a back insulating layer 78 may be formed. Various processes may be applied to form the back wiring layer 76 and the back insulating layer 78. Thereby, the back wiring portion 70 may be formed.

In the drawing and the above description, the through connector 50 is formed after forming the gate structure 32 and the source and drain patterns 34 included in the second semiconductor device 200 in the second area A2, but example embodiments are not limited thereto. In some example embodiments, after the through connector 50 is formed, the gate structure 32 and the source and drain patterns 34 included in the second semiconductor device 200 may be formed. In some example embodiments, the through connector 50 may be formed during a process of forming a portion included in the second semiconductor device 200.

The manufacturing process of the second semiconductor device 200 with reference to FIGS. 8 and 9 may be an example. Accordingly, any of various manufacturing processes may be applied as a manufacturing method of the second semiconductor device 200.

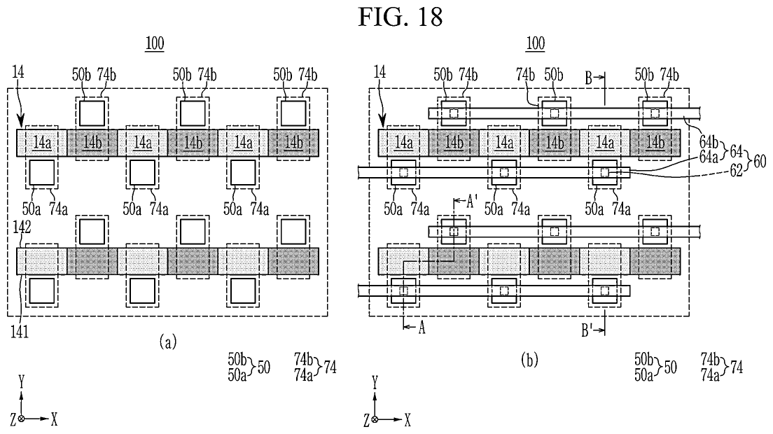

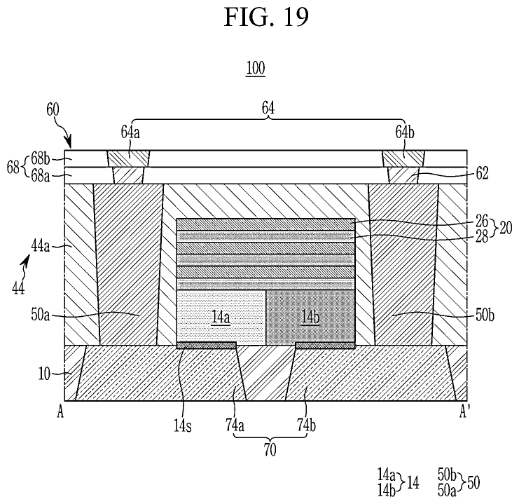

Hereinafter, a first semiconductor device and an integrated circuit including the same according to an example embodiment different from the above example embodiment will be described in more detail with reference to FIGS. 18 and 19. To the extent that an element is not described in detail below, it may be understood that the element is at least similar to a corresponding element that has been described elsewhere within the present disclosure

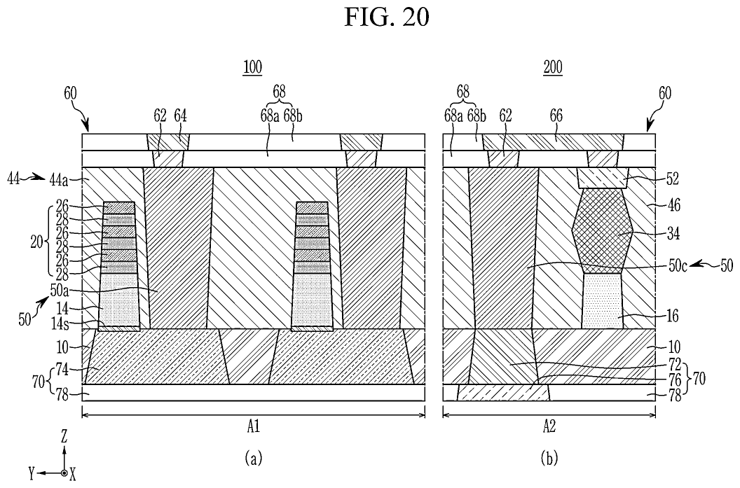

FIG. 18 is a plan view illustrating a first semiconductor device according to an example embodiment, and FIG. 19 is a cross-sectional view taken along a line A-A of FIG. 18. FIG. 20 is a cross-sectional view illustrating the first semiconductor device taken along a line B-B′ in FIG. 18 together with a second semiconductor device. FIG. 20 illustrates the corresponding part in FIG. 4. (b) of FIG. 20 illustrates a cross section (YZ plane of the drawing) of source and drain patterns perpendicular to a first direction (X-axis direction of the drawing), and illustrates a second wiring layer 66 and a third through connector 50c connected to source and drain patterns 34 conceptually.

Referring to FIG. 18 and FIG. 20, a first semiconductor device 100 according to an example embodiment may include a diode pattern 14 on a base insulating layer 10, an insulating layer 40 (e.g., a first insulating layer 44), a through connector 50, a wiring portion 60, and a back contact portion 74. Herein, the through connector 50 and the back contact portion 74 may form a connector connecting the diode pattern 14 and the wiring portion 60.

In an example embodiment, the first insulating layer 44 covering the diode pattern 14 on the base insulating layer 10 may include a first insulating portion 44a. A stacked structure 20 including a channel layer 26 and a sacrificial layer 28 may be on the diode pattern 14. For example, a semiconductor layer may be on the diode pattern 14. Accordingly, the first insulating portion 44a may cover the stacked structure 20 on the diode pattern 14.

That is, the stacked structure 20 formed in a process of manufacturing a second semiconductor device including a BSPDN structure may be remained without being removed. Accordingly, the manufacturing process may be simplified because there is no need to add a process for removing the stacked structure 20.

However, example embodiments are not limited thereto. In some example embodiments, the first insulating layer 44 may include the first insulating portion 44a and a second insulating portion 44b (refer to FIG. 2), which is an upper insulating portion on the diode pattern 14, by performing processes illustrated in FIGS. 11 to 13.

The through connector 50 may be at a periphery of the diode pattern 14. The through connector 50 may extend through the insulating layer 40 (e.g., the first insulating layer 44) to electrically connect the diode pattern 14 and a first wiring layer 64. For example, the through connector 50 may be in contact with a back contact portion 74 connected to the diode pattern 14 and the contact via 62. In this instance, the through connector 50 may include a first through connector 50a connected to the first conductive region 14a and a second through connector 50b connected to the second conductive region 14b.

In an example embodiment, the through connector 50 extending through the first insulating layer 44 may be spaced apart from the diode pattern 14. The first through connector 50a may be at a portion where the first conductive region 14a is positioned in the first direction (X-axis direction in the drawing). The first through connector may be spaced apart from a first side surface 141 of the diode pattern 14 in the second direction (Y-axis direction in the drawing) at a certain distance at a first side of the diode pattern 14. The second through connector 50b may be at a portion where the second conductive region 14b is positioned in the first direction. The second through connector 50b may be spaced apart from the second side 142 of the diode pattern 14 at a certain distance at a second side of the diode pattern 14, which is opposite to the first side in the second direction.

For example, the first through connector 50a may be positioned to correspond to a central portion of the first conductive region 14a in the first direction, and the second through connector 50b may be positioned to correspond to a central portion of the second conductive region 14b in the first direction. Accordingly, a distance between the first through connector 50a and the first conductive region 14a and a distance between the second through connector 50b and the second conductive region 14b may be reduced, and the first through connector 50a and the second through connector 50b may be stably formed.

The back contact portion 74 may extend through at least a partial portion of the base insulating layer 10, and may electrically connect a back surface of the diode pattern 14 and a back surface of the through connector 50. For example, a first back contact portion 74a may be in contact with the first through connector 50a, and a second back contact portion 74b may be in contact with the second through connector 50b.

In this instance, a width of the back contact portion 74 in the first direction (X-axis direction of the drawing) may be greater than a width of the through connector 50 in the first direction, and a length of the back contact portion 74 in the second direction (Y-axis direction in the drawing) may be greater than a width of the through connector 50 in the second direction. Accordingly, the through connector 50 may be stably connected to the back contact portion 74.

In an embodiment, the back contact portion 74 may include a first back contact portion 74a and a second back contact portion 74b. The first back contact portion 74a may extend in the second direction (Y-axis direction in the drawing) to connect the first conductive region 14a and the first through connector 50a. The second back contact portion 74b may extend in the second direction to connect the second conductive region 14b and the second through connector 50b. Thus, the back surface of the diode pattern 14 and the back surface of the through connector 50 may be stably electrically connected with each other by connecting the back surface of the diode pattern 14 and the back surface of the through connector 50 through the back contact portion 74.

For example, the diode pattern 14, the first wiring portion 64a, and the second wiring portion 64b may each have a straight shape or a line shape extending in the first direction, and the first back contact portion 74a and the second back contact portion 74b may each have a straight shape or a line shape extending in the second direction.

Based on the diode pattern 14, the first back contact portion 74a and the second back contact portion 74b may extend in opposite directions in the second direction (Y-axis direction in the drawing). In the first direction, the first back contact portion 74a extending to a first side (a lower side in FIG. 18) in the second direction and the second back contact portion 74b extending to a second side (an upper side in FIG. 18) may be alternately positioned from a first end (a left end in FIG. 18) to a second end (a right end in FIG. 18) of the diode pattern 14. For example, the first back contact portion 74a and the second back contact portion 74b may be arranged in a zigzag shape.

In an example embodiment, the back contact portion 74 may include at least one of titanium, tungsten, nickel, cobalt, tantalum, molybdenum, copper, aluminum, gold, tin, manganese, ruthenium, beryllium, or an alloy thereof. The back contact portion 74 may include one layer or a plurality of layers. The back contact portion 74 may be a portion of the back wiring portion 70, and may include a same material as the back contact via 72 or the back wiring layer 76. However, example embodiments are not limited thereto, and the back contact portion 74 may include a different material from that of the back contact via 72 or the back wiring layer 76.

In this instance, a metal-semiconductor compound layer 14s may be at a boundary between the back surface (e.g., bottom surface) of the first conductive region 14a and the front surface (e.g., top surface) of the first back contact portion 74a. That is, the first back contact portion 74a may be electrically connected to the first conductive region 14a through the metal-semiconductor compound layer 14s. Similarly, the metal-semiconductor compound layer 14s may be at a boundary between the back surface (e.g., bottom surface) of the second conductive region 14b and the front surface (e.g., top surface) of the second back contact portion 74b. That is, the second back contact portion 74b may be electrically connected to the second conductive region 14b through the metal-semiconductor compound layer 14s.

The metal-semiconductor compound layer 14s may include a compound of metal and a semiconductor material included in the diode pattern 14. For example, the metal-semiconductor compound layer 14s may include metal silicide, e.g., at least one of titanium silicide, tungsten silicide, nickel silicide, cobalt silicide, tantalum silicide, or molybdenum silicide. The metal included in the metal-semiconductor compound layer 14s may be the same as or different from a metal included in the back contact portion 74. However, example embodiments are not limited to a material of the metal-semiconductor compound layer 14s.

The description of the second semiconductor device 200 with reference to FIGS. 3 and 4 may be applied to a second semiconductor device 200.

According to an example embodiment, stability of a connection structure may be improved by connecting the diode pattern 14 and the through connector 50 using the back contact portion 74.

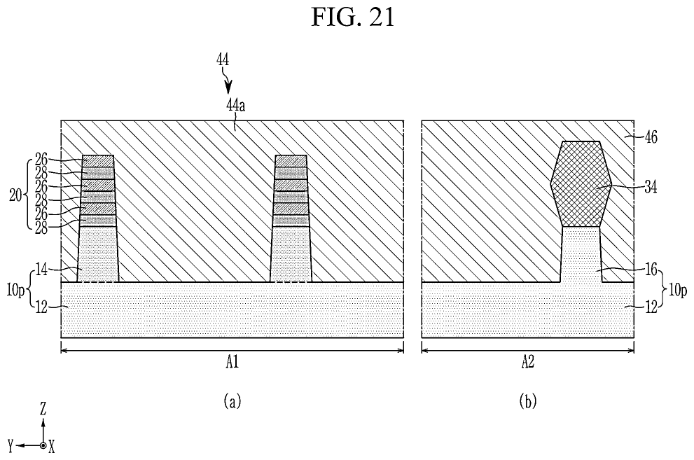

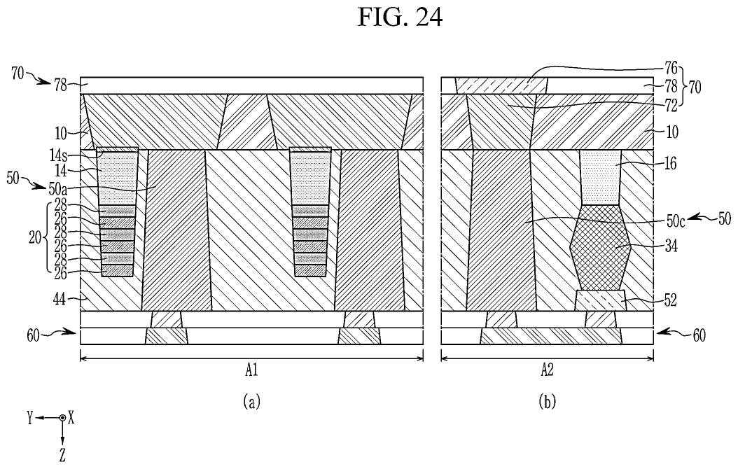

A manufacturing method for the first semiconductor device 100 having the bulk-less structure will be described in detail with reference to FIGS. 21 to 24. As described above, the first semiconductor device 100 together with a second semiconductor device 200 having a BSPDN structure forms an integrated circuit. Hereinafter, a manufacturing method of the first semiconductor device 100 will be described while describing a manufacturing method of the integrated circuit including the first semiconductor device 100 and the second semiconductor device 200.

FIG. 21 to FIG. 24 are cross-sectional views illustrating a manufacturing method for an integrated circuit including a first semiconductor device according to an example embodiment. FIGS. 21 to 24 illustrate portions corresponding to FIG. 20.

As illustrated in FIG. 21, a semiconductor substrate 10p and a stacked structure 20 may be formed, a first insulating layer 44 including a first insulating portion 44a may be formed in a first area A1, a gate structure 32 (refer to FIG. 3) and source and drain patterns 34 included in a second semiconductor device 200 may be formed in a second area A2, and a second insulating layer 46 including a third insulating portion and/or a fourth insulating portion may be formed. In this regard, the description with reference to FIGS. 5 to 10 may be applied as it is.

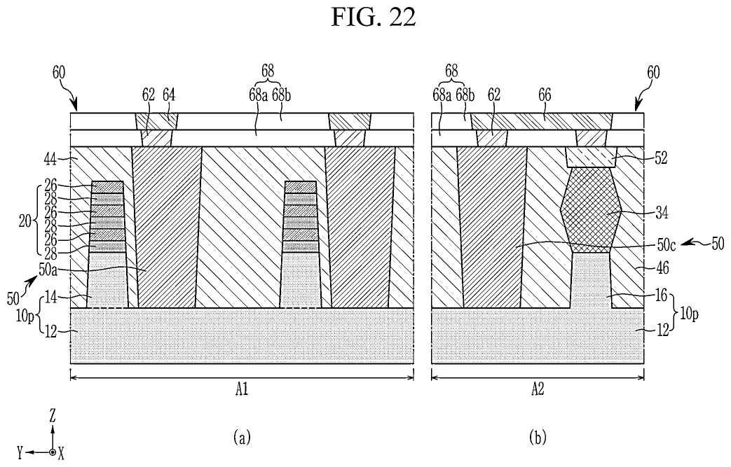

Subsequently, as illustrated in FIG. 22, a through connector 50 may be formed in the first area A1, and a first contact portion 52, a second contact portion 54 (refer to FIG. 3), and a wiring portion 60 may be formed.

In a process of forming the through connector 50, a first through connector 50a and a second through connector 50b may be formed in the first area A1, and a third through connector 50c may be formed in the second area A2. In this regard, the description with reference to FIG. 14 may be applied as it is, except that the through connector 50 is spaced apart from the diode pattern 14 and a process of forming the metal-semiconductor compound layer 14s is not performed.

The description with reference to FIG. 15 may be applied as it is to the process of forming the first contact portion 52, the second contact portion 54, and the wiring portion 60.

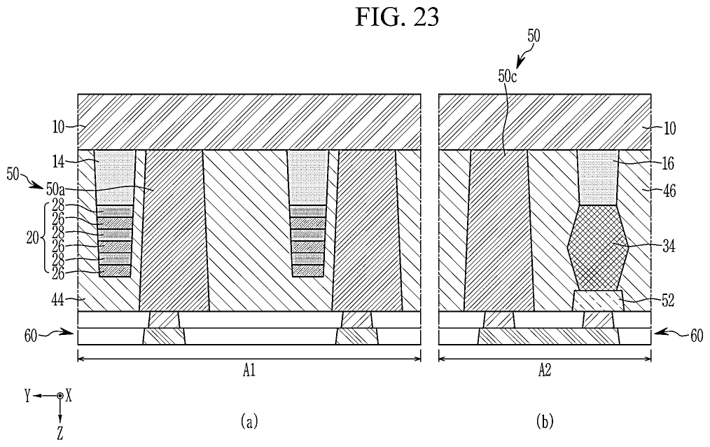

Subsequently, as illustrated in FIG. 23, in a state that a back surface of the semiconductor substrate 10p (refer to FIG. 22) positioned at an upper portion, a bulk portion 12 (refer to FIG. 22) of the semiconductor substrate 10p may be removed and a base insulating layer 10 may be formed.

Subsequently, as illustrated in FIG. 74, a back contact portion 74 may be formed to extend through the base insulating layer 10 in the first area A1, and a back wiring portion 70 including a back contact via 72 extending through the base insulating layer 10 may be formed in the second area A2.

For example, a contact opening may be formed in the first area A1 and the second area A2. In the first area A1, a first contact opening exposing the first through connector 50a and the first conductive region 14a and a second contact opening exposing the second through connector 50b and the second conductive region 14b may be formed. Furthermore, in the second area A2, a third contact opening may be formed through the base insulating layer 10 to expose the third through connector 50c.

In an example embodiment, the metal-semiconductor compound layer 14s may be formed on the back surface of the first conductive region 14a exposed through the first contact opening and on the back surface of the second conductive region 14b exposed through the second contact opening after the first to third contact openings. For example, a metal layer may be formed on the back surface of the first conductive region 14a and the back surface of the second conductive region 14b and heat-treated to form the metal-semiconductor compound layer 14s. However, example embodiments are not limited thereto. In some example embodiments, the metal-semiconductor compound layer 14s may be formed through heat treatment in a subsequent process without performing heat treatment after forming the metal layer. In some example embodiments, a process of forming the metal-semiconductor compound layer 14s might not be performed separately. In this instance, through the heat treatment process performed in the subsequent process, a semiconductor material of the first or second conductive region 14a or 14b and metal of the first or second back contact portion 74 may be chemically bonded to each other, thereby forming the metal-semiconductor compound layer 14s.

The back contact portion 74 and the back contact via 72 may be formed by filling the first contact opening, the second contact opening, and the third contact opening with a conductive material. For example, a planarization process may be performed after filling the first contact opening, the second contact opening, and the third contact opening with the conductive material. The planarization process may be performed, e.g., by a chemical mechanical etching process.

A back wiring layer 76 and a back insulating layer 78 may be formed. Various processes may be applied to form the back wiring layer 76 and the back insulating layer 78. Thereby, the back wiring portion 70 may be formed.

In the drawing and the above description, the through connector 50 is formed after forming the gate structure 32 and the source and drain patterns 34 included in the second semiconductor device 200 in the second area A2, but example embodiments are not limited thereto. After the through connector 50 is formed, the gate structure 32 and the source and drain pattern 34 included in the second semiconductor device 200 may be formed. The through connector 50 may be formed during a process of forming a portion included in the second semiconductor device 200.

Although some example embodiments have been described in detail above, the scope of the present disclosure is not limited thereto. Various modifications and improvements made by those skilled in the art using the basic concepts of the present disclosure as defined in the following claims may also fall within the scope of the present disclosure.

What is claimed is:

1. A semiconductor device comprising:
a diode pattern on a base insulating layer, the diode pattern including a first conductive region and a second conductive region having opposite conductivity types to each other;
an insulating layer covering the diode pattern on the base insulating layer;
a wiring portion on the insulating layer; and
a through connector extending through the insulating layer at a periphery of the diode pattern to electrically connect the diode pattern and the wiring portion.

2. The semiconductor device of claim 1, wherein the through connector includes a first through connector and a second through connector, the first through connector connected to the first conductive region at a first side of the diode pattern, the second through connector connected to the second conductive region at a second side of the diode pattern opposite to the first side.

3. The semiconductor device of claim 2, wherein the first conductive region and the second conductive region are adjacent to each other in a first direction,
the first through connector is at the first side of the diode pattern in a second direction, the second direction crossing the first direction, and
the second through connector is at the second side of the diode pattern in the second direction.

4. The semiconductor device of claim 1, wherein the first conductive region includes a plurality of first conductive regions and the second conductive region includes a plurality of second conductive regions,
the plurality of first conductive regions and the plurality of second conductive regions are alternately positioned in a first direction, and
the through connector includes;
a plurality of first through connectors at a first side of the diode pattern in a second direction crossing the first direction and connected to the plurality of first conductive regions, respectively, and
a plurality of second through connectors at a second side of the diode pattern opposite to the first side in the second direction and connected to the plurality of second conductive regions, respectively.

5. The semiconductor device of claim 4, wherein the wiring portion includes
a first wiring portion extending in the first direction at the first side of the diode pattern and electrically connected to the plurality of first through connectors, and
a second wiring portion extending in the first direction at the second side of the diode pattern and electrically connected to the plurality of second through connectors.

6. The semiconductor device of claim 5, wherein the diode pattern, the first wiring portion, and the second wiring portion each has a straight shape extending in the first direction.

7. The semiconductor device of claim 1, wherein a side surface of the diode pattern and a side surface of the through connector are connected to each other.

8. The semiconductor device of claim 7, wherein a metal-semiconductor compound layer is at a boundary between the side surface of the diode pattern and the side surface of the through connector.

9. The semiconductor device of claim 7, wherein the insulating layer includes an upper insulating portion on the diode pattern.

10. The semiconductor device of claim 1, wherein the diode pattern and the through connector are spaced apart from each other, and
the semiconductor device further comprises a back contact portion extending through at least a portion of the base insulating layer and electrically connecting a back surface of the diode pattern and a back surface of the through connector.

11. The semiconductor device of claim 10, wherein the first conductive region and the second conductive region are adjacent to each other in a first direction,
the through connector includes
a first through connector at a first side of the diode pattern in a second direction crossing the first direction, and
a second through connector at a second side of the diode pattern opposite to the first side in the second direction, and
the back contact portion includes
a first back contact portion extending in the second direction and electrically connecting the first conductive region to the first through connector, and
a second back contact portion extending in the second direction and electrically connecting the second conductive region to the second through connector.

12. The semiconductor device of claim 11, wherein the first back contact portion and the second back contact portion extend in the second direction and are opposite to each other based on the diode pattern.

13. The semiconductor device of claim 10, wherein a metal-semiconductor compound layer is at a boundary between the back surface of the diode pattern and the back contact portion.

14. The semiconductor device of claim 10, further comprising:
a semiconductor layer on the diode pattern, or
the insulating layer includes an upper insulating portion on the diode pattern.

15. A semiconductor device comprising:
a diode pattern on a base insulating layer, the diode pattern including a first conductive region and a second conductive region having opposite conductivity types to each other;
an insulating layer covering the diode pattern on the base insulating layer;
a wiring portion on the insulating layer; and
a connector electrically connecting a side surface or a back surface of the diode pattern and the wiring portion.

16. The semiconductor device of claim 15, wherein the connector includes a through connector extending through the insulating layer and connected to a side surface of the diode pattern.

17. The semiconductor device of claim 15, wherein the connector includes a through connector and a back contact portion, the through connector spaced apart from the diode pattern and extending through the insulating layer, the back contact portion extending through at least a portion of the base insulating layer and electrically connecting the back surface of the diode pattern to a back surface of the through connector.

18. An integrated circuit comprising:
a base insulating layer having a first region and a second region;
a first semiconductor device in the first region; and
a second semiconductor device in the second region, the second semiconductor device including a back power distribution network (BSPDN) structure, the BSPDN structure including a back wiring portion, the back wiring porting including a back contact via extending through the base insulating layer,
wherein the first semiconductor device includes,
a diode pattern on the base insulating layer, the diode pattern including a first conductive region and a second conductive region, the first conductive region and the second conductive region having opposite conductivity types to each other,
an insulating layer covering the diode pattern on the base insulating layer,
a wiring portion on the insulating layer, and
a through connector extending through the insulating layer at a periphery of the diode pattern and electrically connecting the diode pattern to the wiring portion.

19. The integrated circuit of claim 18, wherein the second semiconductor device includes:
an active pattern on the base insulating layer;
a gate structure on the active pattern;
a pair of source and drain patterns at both sides of the active pattern, respectively; and
another through connector extending through the insulating layer at a periphery of a corresponding one of the pair of source and drain patterns and electrically connecting the corresponding one of the pair of source and drain patterns and the back wiring portion via the wiring portion.

20. The integrated circuit of claim 19, wherein the active pattern includes a plurality of channel patterns having a nanosheet shape spaced apart from each other in a thickness direction.
